(19) United States
(12) Patent Application Publication
(10) Pub. No.: US 2025/0254997 A1
(43) Pub. Date: Aug. 7, 2025

(54) DISPLAY DEVICE, METHOD OF MEASURING RESISTANCE OF THE DISPLAY DEVICE, AND ELECTRONIC DEVICE INCLUDING THE DISPLAY DEVICE

(71) Applicant: Samsung Display Co., LTD., Yongin-si (KR)

(72) Inventors: WONTAE KIM, Yongin-si (KR); JAE-HAN LEE, Yongin-si (KR)

(21) Appl. No.: 18/984,689

(22) Filed: Dec. 17, 2024

(30) Foreign Application Priority Data
Feb. 7, 2024 (KR) 10-2024-0018668

(51) Int. Cl. H10D 86/40; H10D 86/60

(52) U.S. Cl. CPC H10D 86/443; H10D 86/60

(57) ABSTRACT

A display device includes: a substrate including a display area in which a plurality of pixels are located and a non-display area in contact with the display area; an outer wiring in the non-display area on the substrate; a 1-1 substrate pad in the non-display area on the substrate and connected to the outer wiring; a first chip-on film attached to one side of the substrate and including a 1-1 output pad connected to the 1-1 substrate pad and a 1-1 input pad connected to the 1-1 output pad through a 1-1 line; and a circuit board attached to one side of the first chip-on film and including a 1-1 circuit board pad connected to the 1-1 input pad and a 1-1 test pad connected to the 1-1 circuit board pad through a 1-1 test line.

### CROSS-REFERENCE TO RELATED APPLICATION

The present application claims priority to and benefits of Korean Patent Application No. 10-2024-0018668, filed on Feb. 7, 2024, in the Korean Intellectual Property Office, the entire disclosure of which is incorporated herein by reference.

### BACKGROUND

### 1. Field

Aspects of some embodiments relate to a display device, a method of measuring resistance of the display device, and an electronic device including the display device.

### 2. Description of the Related Art

A display device is a device that displays images for providing visual information to users. Among display devices, an organic light emitting diode display has recently attracted attention.

A display device may include a substrate on which a plurality of pixels are arranged, a chip-on film located at one side of the substrate, and a circuit board attached to one side of the chip-on film. The substrate and the chip-on film may be attached to each other in a bonding area. Resistance of the bonding area may be measured through a test pad included in the circuit board.

The above information disclosed in this Background section is only for enhancement of understanding of the background and therefore the information discussed in this Background section does not necessarily constitute prior art.

### SUMMARY

Aspects of some embodiments include a display device with relatively improved quality.

Aspects of some embodiments include a method of measuring resistance of the display device.

Aspects of some embodiments include an electronic device including the display device.

A display device according to some embodiments includes a substrate including a display area in which a plurality of pixels are located and a non-display area in contact with the display area, an outer wiring in the non-display area on the substrate, a 1-1 substrate pad in the non-display area on the substrate and connected to the outer wiring, a first chip-on film attached to one side of the substrate and including a 1-1 output pad connected to the 1-1 substrate pad and a 1-1 input pad connected to the 1-1 output pad through a 1-1 line, and a circuit board attached to one side of the first chip-on film and including a 1-1 circuit board pad connected to the 1-1 input pad and a 1-1 test pad connected to the 1-1 circuit board pad through a 1-1 test line.

According to some embodiments, the outer wiring may be an anti-static wiring.

According to some embodiments, the display device may further include a 1-2 substrate pad in the non-display area on the substrate and adjacent to the 1-1 substrate pad, a 1-2 output pad included in the first chip-on film, connected to the 1-2 substrate pad, and adjacent to the 1-1 output pad, a 1-2 input pad included in the first chip-on film, connected to the 1-2 output pad through a 1-2 line, and adjacent to the 1-1 input pad, a 1-2 circuit board pad included in the circuit board, connected to the 1-2 input pad, and adjacent to the 1-1 circuit board pad, and a 1-2 test pad included in the circuit board, connected to the 1-2 circuit board pad through a 1-2 test line, and adjacent to the 1-1 test pad.

According to some embodiments, the display device may further include a 1-3 input pad included in the first chip-on film and adjacent to the 1-2 input pad.

According to some embodiments, the 1-3 input pad may be connected to the 1-2 line through a 1-3 line.

According to some embodiments, the display device may further include a 1-3 substrate pad in the non-display area on the substrate and adjacent to the 1-2 substrate pad, a 1-3 output pad included in the first chip-on film, connected to the 1-3 substrate pad, and adjacent to the 1-2 output pad, a 1-3 circuit board pad included in the circuit board, connected to the 1-3 input pad, and adjacent to the 1-2 circuit board pad, and a 1-3 test pad included in the circuit board, connected to the 1-3 circuit board pad through a 1-3 test line, and adjacent to the 1-2 test pad.

According to some embodiments, the display device may further include a 1-4 substrate pad in the non-display area on the substrate and adjacent to the 1-3 substrate pad, a 1-4 output pad included in the first chip-on film, connected to the 1-4 substrate pad, and adjacent to the 1-3 output pad, a 1-4 input pad included in the first chip-on film, connected to the 1-4 output pad through a 1-4 line, and adjacent to the 1-3 input pad, a 1-4 circuit board pad included in the circuit board, connected to the 1-4 input pad, and adjacent to the 1-4 circuit board pad, and a 1-4 test pad included in the circuit board, connected to the 1-4 circuit board pad through a 1-4 test line, and adjacent to the 1-3 test pad.

According to some embodiments, the 1-2 substrate pad and the 1-4 substrate pad may be connected to each other through a 1-1 bridge line.

According to some embodiments, the outer wiring may be connected to the 1-1 bridge line.

According to some embodiments, the outer wiring and the 1-1 bridge line may be on different layers.

According to some embodiments, the 1-1 substrate pad may be connected to one end of the outer wiring.

According to some embodiments, the display device may further include a 2-1 substrate pad in the non-display area on the substrate and connected to other end of the outer wiring and a second chip-on-film attached to one side of the substrate, spaced apart from the first chip-on film, and including a 2-1 output pad connected to the 2-1 substrate pad and a 2-1 input pad connected to the 2-1 output pad through a 2-1 line.

According to some embodiments, the circuit board may include a 2-1 circuit board pad connected to the 2-1 input pad and a 2-1 test pad connected to the 2-1 circuit board pad through the 2-1 test line.

According to some embodiments, the display device may further include a 2-2 substrate pad in the non-display area on the substrate and adjacent to the 2-1 substrate pad, a 2-2 output pad included in the second chip-on film, connected to the 2-2 substrate pad, and adjacent to the 2-1 output pad, a 2-2 input pad included in the second chip-on film, connected to the 2-2 output pad through a 2-2 line, and adjacent to the 2-1 input pad, a 2-2 circuit board pad included in the circuit board, connected to the 2-2 input pad, and adjacent to the 2-1 circuit board pad, and a 2-2 test pad included in the circuit board, connected to the 2-2 circuit board pad through a 2-2 test line, and adjacent to the 2-1 test pad.

According to some embodiments, the display device may further include a 2-3 input pad included in the second chip-on film and adjacent to the 2-2 input pad.

According to some embodiments, the 2-3 input pad may be connected to the 2-2 line through a 2-3 line.

According to some embodiments, the display device may further include a 2-3 substrate pad in the non-display area on the substrate and adjacent to the 2-2 substrate pad, a 2-3 output pad included in the second chip-on film, connected to the 2-3 substrate pad, and adjacent to the 2-2 output pad, a 2-3 circuit board pad included in the circuit board, connected to the 2-3 input pad, and adjacent to the 2-2 circuit board pad, and a 2-3 test pad included in the circuit board, connected to the 2-3 circuit board pad through a 2-3 test line, and adjacent to the 2-2 test pad.

According to some embodiments, the display device may further include a 2-4 substrate pad in the non-display area on the substrate and adjacent to the 2-3 substrate pad, a 2-4 output pad included in the second chip-on film, connected to the 2-4 substrate pad, and adjacent to the 2-3 output pad, a 2-4 input pad included in the second chip-on film, connected to the 2-4 output pad through a 2-4th line, and adjacent to the 2-3 input pad, a 2-4 circuit board pad included in the circuit board, connected to the 2-4 input pad, and adjacent to the 2-3 circuit board pad, and a 2-4 test pad included in the circuit board, connected to the 2-4 circuit board pad through a 2-4 test line, and adjacent to the 2-3 test pad.

According to some embodiments, in a method of measure resistance of a display device, the method includes connecting a first output pad included in a chip-on film to a first substrate pad in a non-display area of a substrate, connecting a first input pad included in the chip-on film to a first circuit board pad included in a circuit board, and connecting a first terminal of an ammeter to a first test pad included in the circuit board.

According to some embodiments, the first substrate pad may be connected to an outer wiring,

According to some embodiments, the first input pad may be connected to the first output pad through a first line.

According to some embodiments, the first test pad may be connected to the first circuit board pad through a first test line.

According to some embodiments, the method may further include connecting a second output pad included in the chip-on film to a second substrate pad in the non-display area of the substrate, connecting a second input pad connected to the second output pad through a second line to a second circuit board pad included in the circuit board, connecting a second terminal of the ammeter to a second test pad included in the circuit board and connected to the second circuit board pad through a second test line, connecting a first terminal of a voltmeter to a third test pad included in the circuit board, and connecting a second terminal of the voltmeter to a fourth test pad included in the circuit board.

According to some embodiments, the second substrate pad may be adjacent to the first substrate.

According to some embodiments, the second circuit board pad may be adjacent to the first circuit board pad.

According to some embodiments, the second test line may be adjacent to the first test line.

According to some embodiments, the third test pad may be adjacent to the second test pad.

According to some embodiments, the fourth test pad may be adjacent to the third test pad.

According to some embodiments, the method may further include forming a bridge line connecting the outer wiring and the second substrate pad.

According to some embodiments, the connecting the first terminal of the ammeter to the first test pad may be performed when a voltage is not applied to the substrate through the outer wiring.

An electronic device according to some embodiments includes a substrate including a display area in which a plurality of pixels are located and a non-display area in contact with the display area, an outer wiring in the non-display area on the substrate, a 1-1 substrate pad in the non-display area on the substrate and connected to the outer wiring, a first chip-on film attached to one side of the substrate and including a 1-1 output pad connected to the 1-1 substrate pad and a 1-1 input pad connected to the 1-1 output pad through a 1-1 line, a circuit board attached to one side of the first chip-on film and including a 1-1 circuit board pad connected to the 1-1 input pad and a 1-1 test pad connected to the 1-1 circuit board pad through a 1-1 test line, and a memory device configured to store data.

A display device according to some embodiments may include a substrate including a display area in which a plurality of pixels are located and a non-display area in contact with the display area, an outer wiring in the non-display area on the substrate, a 1-1 substrate pad in the non-display area on the substrate and connected to the outer wiring, a first chip-on film attached to one side of the substrate and including a 1-1 output pad connected to the 1-1 substrate pad and a 1-1 input pad connected to the 1-1 output pad through a 1-1 line, and a circuit board attached to one side of the first chip-on film and including a 1-1 circuit board pad connected to the 1-1 input pad and a 1-1 test pad connected to the 1-1 circuit board pad through a 1-1 test line.

Accordingly, each of the number of substrate pads, the number of input pads, the number of output pads, and the number of circuit board pads may be relatively reduced. Accordingly, each of widths of the substrate pads, widths of the input pads, widths of the output pads, and widths of the circuit board pads may be relatively increased. In addition, sufficient space may be secured in the substrate, the first chip-on film, and the circuit board.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments.

FIG. 2 is a circuit diagram illustrating a pixel included in the display device of FIG. 1.

FIG. 3 is a cross-sectional view illustrating a pixel included in a display device of FIG. 1.

FIG. 4 is a plan view illustrating a substrate, a plurality of chip-on films, and a circuit board included in the display device of FIG. 3.

FIG. 5 is an enlarged plan view of the portion A of FIG. 4.

FIG. 6 is an enlarged plan view of the portion B of FIG. 4.

FIG. 7 is a plan view illustrating the display device of FIG. 1.

FIG. 8 is an enlarged plan view of the portion X of FIG. 7.

FIG. 9 is an enlarged plan view of the portion Y of FIG. 7.

FIG. 10 is a block diagram illustrating an electronic device according to embodiments.

FIG. 11 is a diagram illustrating an example in which the electronic device of FIG. 10 is implemented as a smart phone.

### DETAILED DESCRIPTION

Hereinafter, display devices according to some embodiments will be described in more detail with reference to the accompanying drawings. The same reference numerals are used for the same components in the drawings, and some redundant descriptions of the same components may be omitted.

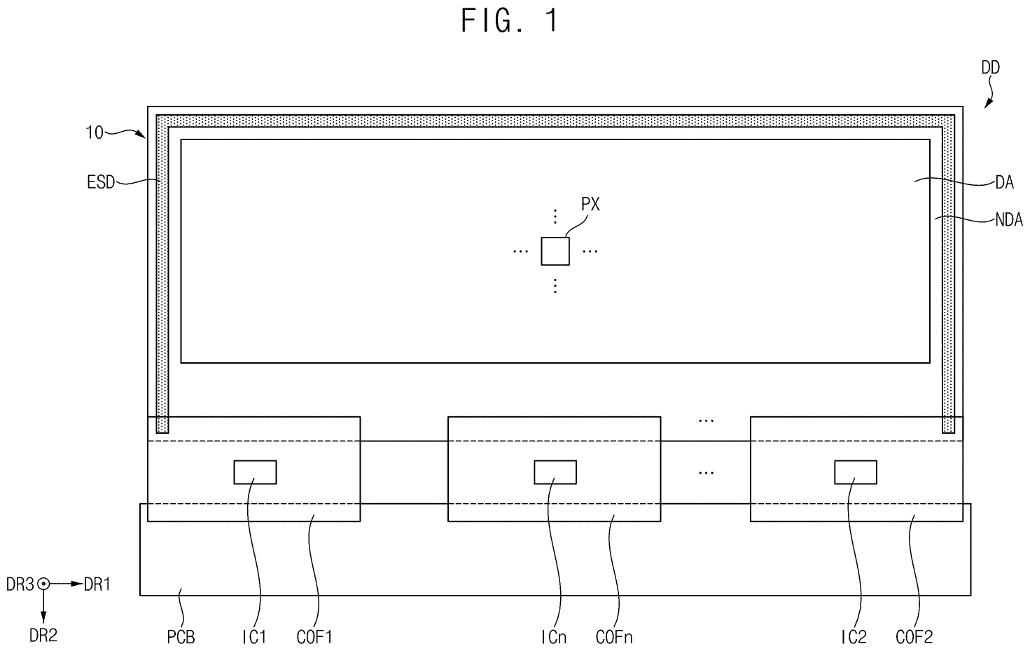

FIG. 1 is a plan view illustrating a display device according to some embodiments.

Referring to FIG. 1, a display device DD according to some embodiments may include a substrate 10, a plurality of chip-on films, and a circuit board PCB.

The substrate 10 may include a display area DA and a non-display area NDA. The display area DA may be defined as an area that emits light. The non-display area NDA may be defined as an area in which components for transmitting a signal to the display area DA are located. According to some embodiments, the non-display area NDA may be located in a periphery (e.g., outside a footprint) of the display area DA.

A plurality of pixels may be located in the display area DA. For example, a pixel PX may be located in the display area DA. Each of the plurality of pixels may emit light based on a signal applied from the non-display area NDA. For example, the plurality of pixels may be repeatedly arranged in a first direction DR1 and a second direction DR2 crossing the first direction DR1. Accordingly, the display area DA may emit light over entire area and display images.

The non-display area NDA may contact the display area DA. For example, the non-display area NDA may be arranged around the display area DA. For example, the non-display area NDA may surround at least a portion of the display area DA.

The non-display area NDA may include driver for driving the plurality of pixels. For example, the non-display area NDA may include a gate driver, a light emitting driver, a power voltage generator, a timing controller, and the like.

According to some embodiments, an anti-static wiring ESD may be located in the non-display area NDA. For example, the anti-static wiring ESD may be arranged to surround at least a portion of the display area DA.

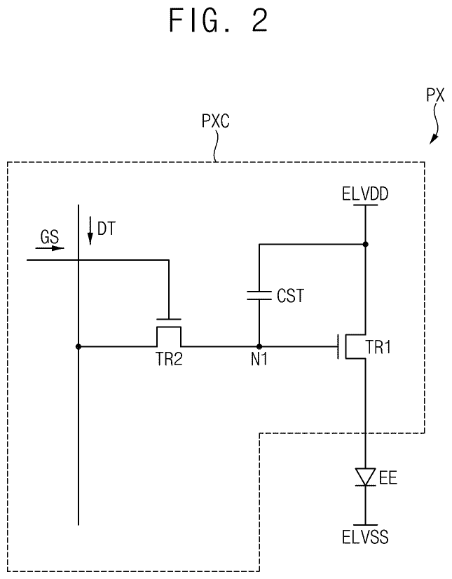

The anti-static wiring ESD may protect the display area DA from static electricity introduced from an outside. For example, the anti-static wiring ESD may protect the display area DA from static electricity introduced from a data line to which a data voltage (e.g., a data voltage DT of FIG. 2) is applied when the display device DD is driven. For example, the anti-static wiring ESD may protect a first transistor (e.g., a first transistor TR1 of FIG. 2) located in the display area DA from static electricity introduced from the data line.

According to some embodiments, the anti-static wiring ESD may include an anti-static transistor. The anti-static transistor may receive gate voltages from power lines, signal lines, and the like. For example, a first power voltage (e.g., a first power voltage ELVSS of FIG. 2) may be applied to the anti-static transistor, but embodiments according to the present disclosure are not limited thereto. For example, the anti-static wiring ESD may be referred to as an outer wiring.

The plurality of chip-on films may be attached to one side of the substrate 10. For example, the plurality of chip-on films may be located on one side of the non-display area NDA of the substrate 10. For example, the plurality of chip-on films may be spaced apart from the display area DA in the second direction DR2

The plurality of chip-on films may include a first chip-on film COF1, a second chip-on film COF2, and an nth chip-on film COFn. The first chip-on film COF1 may be connected to one end of the anti-static wiring ESD. The second chip-on film COF2 may be connected to other end of the anti-static wiring ESD. The nth chip-on film COFn may be located between the first chip-on film COF1 and the second chip-on film COF2. For example, the nth chip-on film COFn may be spaced apart from the first chip-on film COF1 in the first direction DR1. For example, the second chip-on film COF2 may be spaced apart from the nth chip-on film COFn in the first direction DR1.

In this specification, when it is referred that a component is “connected” with another component, it means that the component may be electrically connected with another component.

According to some embodiments, the number of the plurality of chip-on films may be 12. However, embodiments according to the present disclosure are not limited thereto, and the number of the plurality of chip-on films may be changed. For example, the number of the plurality of chip-on films may be equal to or greater than 1 and equal to or less than 11. For example, the number of the plurality of chip-on films may be equal to or greater than 13.

For example, each of the plurality of chip-on films may include a soft material. For example, each of the plurality of chip-on films may include polyethylene terephthalate (“PET”), polyimide (“PI”), or the like. These materials may be used alone or in combination with each other. However, embodiments according to the present disclosure are not limited thereto, and each of the plurality of chip films may include different kinds of materials.

Driving chips may be located on the plurality of chip-on films. For example, a first driving chip IC1 may be located on the first chip-on film COF1. In addition, a second driving chip IC2 may be located on the second chip-on film COF2. In addition, an nth driving chip ICn may be located on the nth chip-on film COFn. Each of the first driving chip IC1, the second driving chip IC2, and the nth driving chip ICn may convert a digital data signal among driving signals into an analog data signal. In addition, each of the first driving chip IC1, the second driving chip IC2, and the nth driving chip ICn may provide the analog data signal to the plurality of pixels.

For example, the first driving chip IC1 may provide an analog data signal to the plurality of pixels through signal lines located on the first chip-on film COF1. In addition, the second driving chip IC2 may provide an analog data signal to the plurality of pixels through signal lines located on the second chip-on film COF2. In addition, the nth driving chip ICn may provide an analog data signal to the plurality of pixels through signal lines located on the nth chip-on film COFn.

The circuit board PCB may be attached to one side of the plurality of chip-on films. For example, the circuit board PCB may be attached to one side of the first chip-on film COF1, the second chip-on film COF2, and the nth chip-on film COFn. For example, the circuit board PCB may be spaced apart from the substrate 10 in the second direction DR2. The circuit board PCB may apply a driving signal, a driving voltage, and the like to the first driving chip IC1, the second driving chip IC2, the nth driving chip ICn, and the plurality of pixels.

According to some embodiments, the number of circuit board PCB may be one. However, embodiments according to the present disclosure are not limited thereto, and the number of circuit board PCB may be changed. For example, the number of circuit board PCB may be 2. For example, the number of circuit board PCB may be equal to or greater than 3.

In this specification, the first direction DR1 and the second direction DR2 crossing the first direction DR1 may be defined. For example, the second direction DR2 may be perpendicular to the first direction DR1. However, embodiments according to the present disclosure are not limited thereto, and the second direction DR2 may form an acute angle or an obtuse angle with the first direction DR1. In addition, a third direction DR3 crossing (e.g., perpendicular to) a plane formed by the first direction DR1 and the second direction DR2 may be defined. For example, the third direction DR3 may be perpendicular to the plane formed by the first direction DR1 and the second direction DR2. However, embodiments according to the present disclosure are not limited thereto, and the third direction DR3 may form an acute angle or an obtuse angle with the plane formed by the first direction DR1 and the second direction DR2.

FIG. 2 is a circuit diagram illustrating a pixel included in the display device of FIG. 1.

Referring to FIG. 2, a pixel PX may include a pixel circuit PXC and a light emitting element EE. The pixel circuit PXC may include a first transistor TR1, a second transistor TR2, and a capacitor CST. Although FIG. 2 illustrates various components in a pixel PX, embodiments according to the present disclosure are not limited thereto, and according to some embodiments, the pixel PX may include additional components without departing from the spirit and scope of embodiments according to the present disclosure.

The first transistor TR1 may apply a driving current to the light emitting element EE. The first transistor TR1 may include a first electrode, a second electrode, and a gate electrode. A second power voltage ELVDD may be applied to the first electrode of the first transistor TR1. The gate electrode of the first transistor TR1 may be connected to a first node N1. The second electrode of the first transistor TR1 may be connected to the light emitting element EE. That is, the first transistor TR1 may be a driving transistor.

The second transistor TR2 may include a first electrode, a second electrode, and a gate electrode. A data voltage DT may be applied to the first electrode of the second transistor TR2. A gate signal GS may be applied to the gate electrode of the second transistor TR2. The second electrode of the second transistor TR2 may be connected to the first node N1. That is, the second transistor TR2 may be a switching transistor.

The capacitor CST may include a first electrode and a second electrode. The second power voltage ELVDD may be applied to the first electrode of the capacitor CST. The second electrode of the capacitor CST may be connected to the first node N1. The capacitor CST may maintain voltage level of the gate electrode of the first transistor TR1 during a deactivation period of the gate signal GS.

The light emitting element EE may include a first electrode and a second electrode. The first electrode of the light emitting element EE may be connected to the second electrode of the first transistor TR1. A first power voltage ELVSS may be applied to the second electrode of the light emitting element EE.

According to some embodiments, the pixel circuit PXC may include two transistors and one capacitor. For example, the pixel circuit PXC may include a first transistor TR1, a second transistor TR2, and a capacitor CST. However, embodiments according to the present disclosure are not limited thereto, and the pixel circuit PXC may include three or more transistors and two or more capacitors.

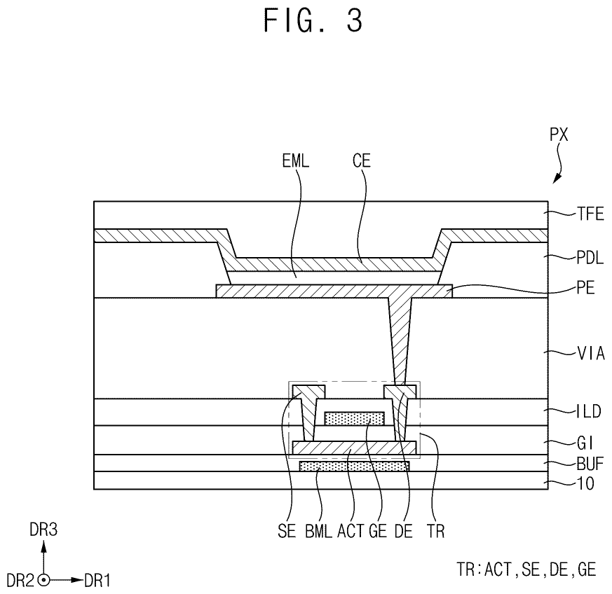

FIG. 3 is a cross-sectional view illustrating a pixel included in a display device of FIG. 1.

Referring to FIG. 3, the pixel may include a substrate 10, a lower metal layer BML, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

The transistor TR may include the active layer ACT, the source electrode SE, the gate electrode GE, and the drain electrode DE. For example, the transistor TR of FIG. 3 may have the same (or substantially the same) configuration as the first transistor TR1 of FIG. 2.

The substrate 10 may include a transparent material or an opaque material. The substrate 10 may be formed of a transparent resin substrate. Example of the transparent resin substrate may include a polyimide substrate. In this case, the polyimide substrate may include a first organic layer, a first barrier layer, a second organic layer, and the like.

Alternatively, the substrate 10 may include a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

The lower metal layer BML may be located on the substrate 10. For example, the lower metal layer BML may at least partially overlap the gate electrode GE in a plan view. For example, the lower metal layer BML may at least partially overlap the active layer ACT in the plan view.

For example, the lower metal layer BML may include an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The buffer layer BUF may be located on the substrate 10. The buffer layer BUF may prevent or reduce instances of contaminants such as metal atoms or other impurities diffusing from the substrate 10 to the transistor TR. In addition, the buffer layer BUF can improve flatness of a surface of the substrate 10 when a surface of the substrate 10 is not uniform.

For example, the buffer layer BUF may include an inorganic material such as silicon oxide, silicon nitride, silicon oxynitride, or the like. These materials may be used alone or in combination with each other.

The active layer ACT may be located on the buffer layer BUF. The active layer ACT may include an inorganic semiconductor (e.g., amorphous silicon, polysilicon, a metal oxide semiconductor), an organic semiconductor, or the like. These materials may be used alone or in combination with each other. The active layer ACT may include a source area, a drain area, and a channel area located between the source area and the drain area.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be located on the buffer layer BUF. The gate insulating layer GI may sufficiently cover the active layer ACT. For example, The gate insulating layer GI may cover the active layer ACT and may be arranged along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The gate electrode GE may be located on the gate insulating layer GI. The gate electrode GE may overlap the channel area of the active layer ACT in the plan view.

The gate electrode GE may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be located on the gate insulating layer GI. The interlayer insulating layer ILD may sufficiently cover the gate electrode GE. For example, the interlayer insulating layer ILD may cover the gate electrode GE, and may be arranged along a profile of the gate electrode GE.

For example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be located on the interlayer insulating layer ILD. The source electrode SE may be connected to the source area of the active layer ACT through a contact hole penetrating the gate insulating layer GI and the interlayer insulating layer ILD.

The drain electrode DE may be located on the interlayer insulating layer ILD. The drain electrode DE may be connected to the drain area of the active layer ACT through a contact hole penetrating the gate insulating layer GI and the interlayer insulating layer ILD.

For example, the source electrode SE may include a metal, an alloy, a metal nitride, a conductive metal oxide, a transparent conductive material, or the like. These materials may be used alone or in combination with each other. The drain electrode DE and the source electrode SE may be formed through the same process and may include the same material.

The via insulating layer VIA may be located on the interlayer insulating layer ILD. The via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be located on the via insulating layer VIA. The pixel electrode PE may be connected to the drain electrode DE through a contact hole penetrating the via insulating layer VIA.

The pixel electrode PE may include a metal, an alloy, a metal nitride, a conductive metal oxide, a transparent conductive material, or the like. These materials be used alone or in combination with each other. According to some embodiments, the pixel electrode PE may have a stacked structure including ITO/Ag/ITO. For example, the pixel electrode PE may operate as an anode.

The pixel defining layer PDL may be located on the via insulating layer VIA. The pixel defining layer PDL may cover side portions of the pixel electrode PE. In addition, an opening exposing a portion of the upper surface of the pixel electrode PE may be defined in the pixel defining layer PDL.

For example, the pixel defining layer PDL may include an inorganic material or an organic material. According to some embodiments, the pixel defining layer PDL may include an organic material such as an epoxy resin, a siloxane resin, or the like. These materials may be used alone or in combination with each other. According to some embodiments, the pixel defining layer PDL may further include a light blocking material containing a black pigment, a black dye, or the like.

The light emitting layer EML may be located on the pixel electrode PE. The light emitting layer EML may include an organic material that emits light of a color (e.g., a set or predetermined color). For example, the light emitting layer EML may include an organic material that emits red light. However, embodiments according to the present disclosure are not limited thereto, and the light emitting layer EML may emit light of a different color from red light.

The common electrode CE may be located on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

The encapsulation layer TFE may be located on the common electrode CE. The encapsulation layer TFE may prevent or reduce instances of contaminants, impurities, and/or moisture penetrating into the pixel electrode PE, the light emitting layer EML, and the common electrode CE from the outside. The encapsulation layer TFE may include at least one inorganic layer and at least one organic layer.

For example, the inorganic layer may include silicon oxide, silicon nitride, silicon oxynitride, or the like. These materials may be used alone or in combination with each other. The organic layer may include a polymer cured product such as polyacrylate.

Although the pixel PX according to some embodiments has been described with reference to FIG. 3, the pixel PX is not limited to the structure shown in FIG. 3. That is, the pixel PX may include all structures that receive an electrical signal and emit light having a luminance corresponding to the intensity of the electrical signal.

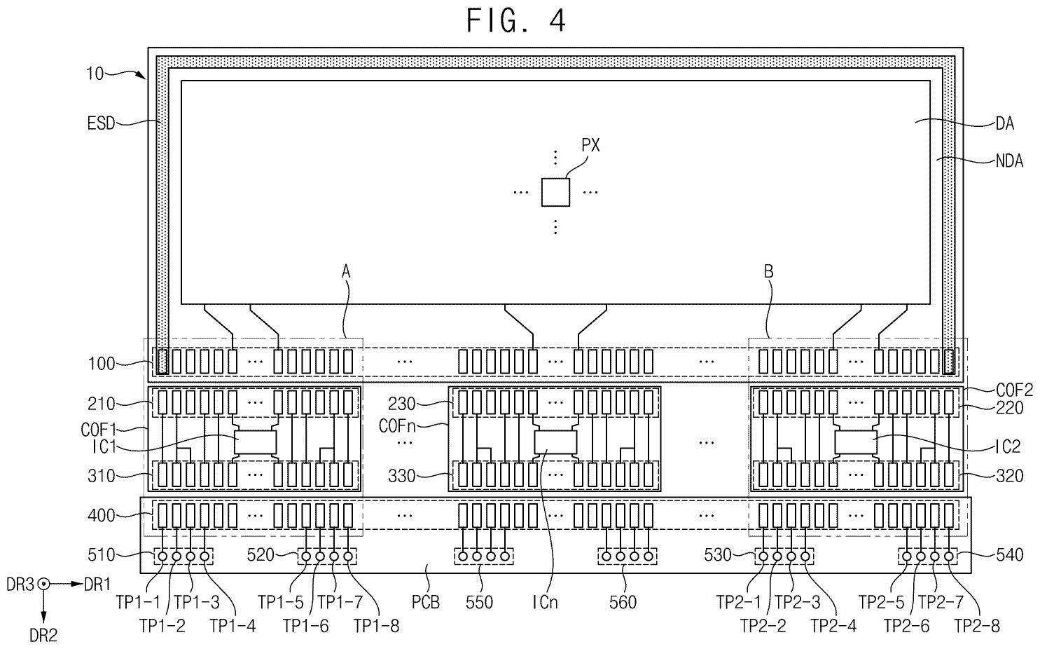

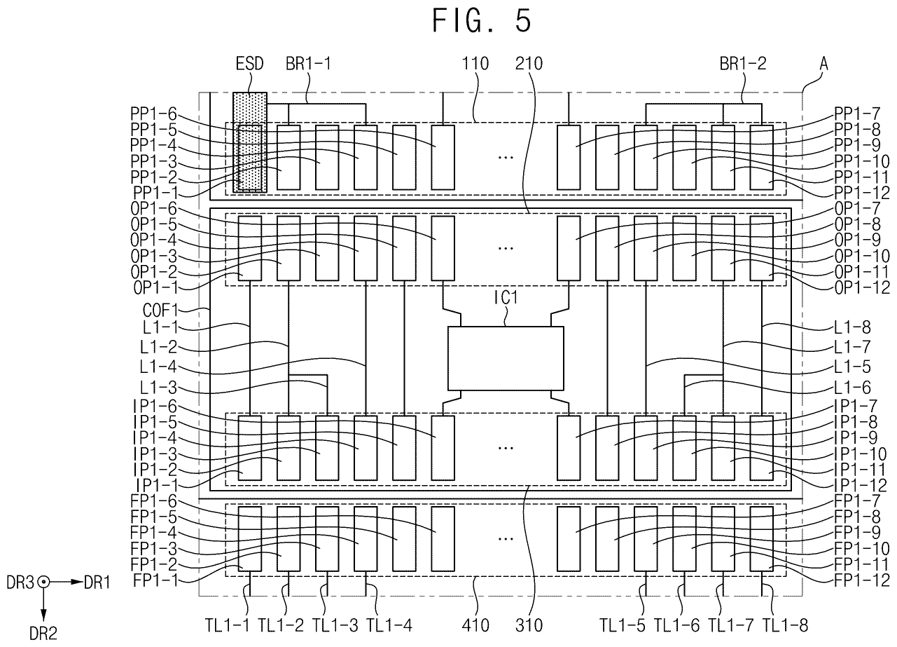

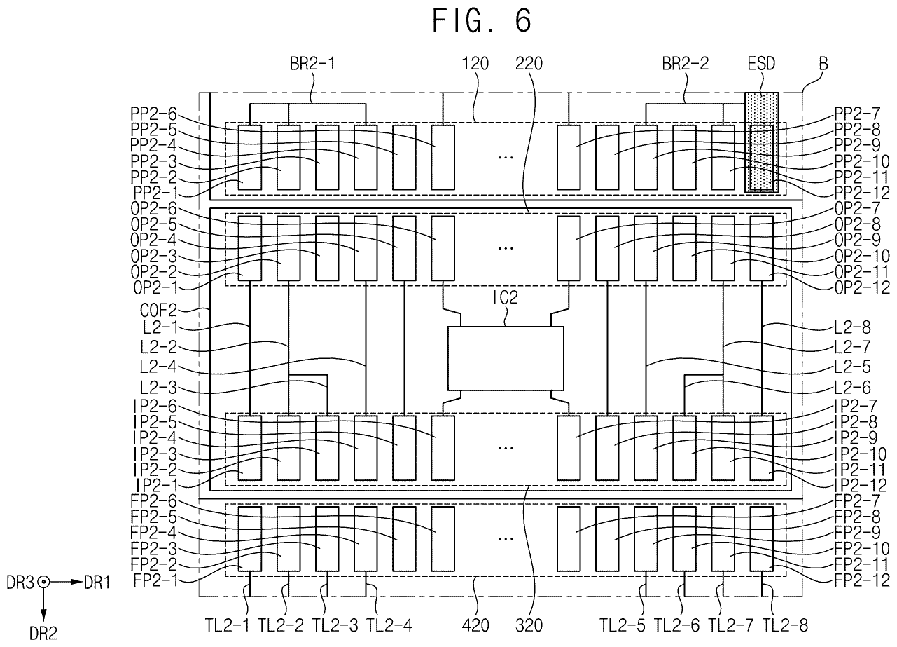

FIG. 4 is a plan view illustrating a substrate, a plurality of chip-on films, and a circuit board included in the display device of FIG. 3. FIG. 5 is an enlarged plan view of portion A of FIG. 4. FIG. 6 is an enlarged plan view of portion B of FIG. 4. For example, FIG. 4 is a plan view illustrating a case where the substrate is not bonded to the plurality of chip-on films and the plurality of chip-on films are not bonded to a circuit board.

Referring to FIG. 4, a plurality of substrate pads 100 may be located on the substrate 10. For example, a plurality of substrate pads 100 may be located in the non-display area NDA. For example, a plurality of substrate pads 100 may be arranged on one side of the non-display area NDA. The plurality of substrate pads 100 may be repeatedly arranged along the first direction DR1.

The first chip-on film COF1 may include a plurality of first output pads 210 and a plurality of first input pads 310. For example, the plurality of first output pads 210 may be located at one side of the first chip-on film COF1. The plurality of first output pads 210 may be repeatedly arranged along the first direction DR1.

For example, the plurality of first input pads 310 may be located on the other side of the first chip-on film COF1. For example, the plurality of first input pads 310 may be spaced apart from the plurality of first output pads 210 with the first driving chip IC1 interposed therebetween. That is, the plurality of first input pads 310 may be spaced apart from the plurality of first output pads 210 in the second direction DR2. The plurality of first input pads 310 may be repeatedly arranged along the first direction DR1.

The second chip-on film COF2 may include a plurality of second output pads 220 and a plurality of second input pads 320. For example, the plurality of second output pads 220 may be located on one side of the second chip-on film COF2. The plurality of second output pads 220 may be repeatedly arranged along the first direction DR1.

For example, the plurality of second input pads 320 may be located on other side of the second chip-on film COF2. For example, the plurality of second input pads 320 may be spaced apart from the plurality of second output pads 220 with the second driving chip IC2 interposed therebetween. That is, the plurality of second input pads 320 may be spaced apart from the plurality of second output pads 220 in the second direction DR2. The plurality of second input pads 320 may be repeatedly arranged along the first direction DR1.

The nth chip-on film COFn may include a plurality of third output pads 230 and a plurality of third input pads 330. For example, the plurality of third output pads 230 may be located on one side of the nth chip-on film COFn. The plurality of third output pads 230 may be repeatedly arranged along the first direction DR1.

For example, the plurality of third input pads 330 may be located on the other side of the nth chip-on film COFn. For example, the plurality of third input pads 330 may be spaced apart from the plurality of third output pads 230 with the nth driving chip ICn interposed therebetween. That is, the plurality of third input pads 330 may be spaced apart from the plurality of third output pads 230 in the second direction DR2. The plurality of third input pads 330 may be repeatedly arranged along the first direction DR1.

The circuit board PCB may include a plurality of circuit board pads 400. For example, the plurality of circuit board pads 400 may be located on one side of the circuit board PCB. The plurality of circuit board pads 400 may be repeatedly arranged along the first direction DR1.

According to some embodiments, the circuit board PCB may further include a plurality of test pads. For example, the circuit board PCB may further include first test pads 510, second test pads 520, third test pads 530, fourth test pads 540, fifth test pads 550, and sixth test pads 560.

The second test pads 520 may be spaced apart from the first test pads 510 in the first direction DR1. The fourth test pads 540 may be spaced apart from the third test pads 530 in the first direction DR1. The sixth test pads 560 may be spaced apart from the fifth test pads 550 in the first direction DR1.

Referring further to FIG. 5, for example, the plurality of first substrate pads 110 may include a 1-1 substrate pad PP1-1, a 1-2 substrate pad PP1-2, a 1-3 substrate pad PP1-3, a 1-4 substrate pad PP1-4, a 1-5 substrate pad PP1-5, a 1-6 substrate pad PP1-6, a 1-7 substrate pad PP1-7, a 1-8 substrate pad PP1-8, a 1-9 substrate pad PP1-9, a 1-10 substrate pad PP1-10, a 1-11 substrate pad PP1-11, and a 1-12 substrate pad PP1-12.

The 1-2 substrate pad PP1-2 may be adjacent to the 1-1 substrate pad PP1-1 in the first direction DR1. The 1-3 substrate pad PP1-3 may be adjacent to the 1-2 substrate pad PP1-2 in the first direction DR1. The 1-4 substrate pad PP1-4 may be adjacent to the 1-3 substrate pad PP1-3 in the first direction DR1. The 1-5 substrate pad PP1-5 may be adjacent to the 1-4 substrate pad PP1-4 in the first direction DR1. The 1-6 substrate pad PP1-6 may be adjacent to the 1-5 substrate pad PP1-5 in the first direction DR1.

The 1-7 substrate pad PP1-7 may be adjacent to the 1-8 substrate pad PP1-8 in a direction opposite to the first direction DR1. The 1-8 substrate pad PP1-8 may be adjacent to the 1-9 substrate pad PP1-9 in the direction opposite to the first direction DR1. The 1-9 substrate pad PP1-9 may be adjacent to the 1-10 substrate pad PP1-10 in the direction opposite to the first direction DR1. The 1-10 substrate pad PP1-10 may be adjacent to the 1-11 substrate pad PP1-11 in the direction opposite to the first direction DR1. The 1-11 substrate pad PP1-11 may be adjacent to the 1-12 substrate pad PP1-12 in the direction opposite to the first direction DR1.

According to some embodiments, the 1-1 substrate pad PP1-1 may be connected to the anti-static wiring ESD. For example, the 1-1-substrate pad PP1-1 may be connected to one end of the anti-static wiring ESD.

According to some embodiments, the 1-2 substrate pad PP1-2 and the 1-4 substrate pad PP1-4 may be connected to each other through a 1-1 bridge line BR1-1. For example, the 1-2 substrate pad PP1-2 may be connected to the 1-1 bridge line BR1-1, and the 1-4 substrate pad PP1-4 may be connected to the 1-1 bridge line BR1-1.

According to some embodiments, the 1-1 bridge line BR1-1 may be located on the same layer as the 1-2 substrate pad PP1-2 and the 1-4 substrate pad PP1-4. For example, the 1-2 substrate pad PP1-2 and the 1-4 substrate pad PP1-4 may be located on the same layer as the source electrode (e.g., the source electrode SE of FIG. 3), and the 1-1 bridge line BR1-1 may also be located on the same layer as the source electrode.

However, embodiments according to the present disclosure are not limited thereto, and according to some embodiments, the 1-1 bridge line BR1-1 may be located on a different layer from the 1-2 substrate pad PP1-2 and the 1-4 substrate pad PP1-4. In this case, the 1-1 bridge line BR1-1 may be connected to the 1-2 substrate pad PP1-2 by a first contact hole, and may be connected to the 1-4 substrate pad PP1-4 by a second contact hole.

According to some embodiments, the 1-1 bridge line BR1-1 may be connected to the anti-static wiring ESD. According to some embodiments, the 1-1 bridge line BR1-1 may be located on a different layer from the anti-static wiring ESD. For example, the anti-static wiring ESD may be located on the same layer as the lower metal layer (e.g., the lower metal layer BML of FIG. 3), and the 1-1 bridge line BR1-1 may be located on the same layer as the source electrode. In this case, the 1-1 bridge line BR1-1 may be connected to the anti-static wiring ESD by a third contact hole.

However, embodiments according to the present disclosure are not limited thereto, and according to some embodiments, the 1-1 bridge line BR1-1 and the anti-static wiring ESD may be located on the same layer.

According to some embodiments, the 1-9 substrate pad PP1-9, the 1-11 substrate pad PP1-11, and the 1-12 substrate pad PP1-12 may be connected to each other through a 1-2 bridge line BR1-2. For example, the 1-9 substrate pad PP1-9 may be connected to the 1-2 bridge line BR1-2, the 1-11 substrate pad PP1-11 may be connected to the 1-2 bridge line BR1-2, and the 1-12 substrate pad PP1-12 may be connected to the 1-2 bridge line BR1-2.

According to some embodiments, the 1-2 bridge line BR1-2 may be located on the same layer as the 1-9 substrate pad PP1-9, the 1-11 substrate pad PP1-11, and the 1-12 substrate pad PP1-12. For example, the 1-9 substrate pad PP1-9, the 1-11 substrate pad PP1-11, and the 1-2 bridge line BR1-2 may be located on the same layer as the source electrode, and the 1-2 bridge line BR1-2 may also be located on the same layer as the source electrode.

However, embodiments according to the present disclosure are not limited thereto, and according to some embodiments, the 1-2 bridge line BR1-2 may be located on a different layer from the 1-9 substrate pad PP1-9, the 1-11 substrate pad PP1-11, and the 1-12 substrate pad PP1-12. In this case, the 1-2 bridge line BR1-2 may be connected to the 1-9 substrate pad PP1-9 by a fourth contact hole, may be connected to the 1-11 substrate pad PP1-11 by a fifth contact hole, and may be connected to the 1-12 substrate pad PP1-12 by a sixth contact hole.

For example, the plurality of first output pads 210 may include a 1-1 output pad OP1-1, a 1-2 output pad OP1-2, a 1-3 output pad OP1-3, a 1-4 output pad OP1-4, a 1-5 output pad OP1-5, a 1-6 output pad OP1-6, a 1-7 output pad OP1-7, a 1-8 output pad OP1-8, a 1-9 output pad OP1-9, a 1-10 output pad OP1-10, a 1-11 output pad OP1-11, and a 1-12 output pad OP1-12.

The 1-2 output pad OP1-2 may be adjacent to the 1-1 output pad OP1-1 in the first direction DR1. The 1-3 output pad OP1-3 may be adjacent to the 1-2 output pad OP1-2 in the first direction DR1. The 1-4 output pad OP1-4 may be adjacent to the 1-3 output pad OP1-3 in the first direction DR1. The 1-5 output pad OP1-5 may be adjacent to the 1-4 output pad OP1-4 in the first direction DR1. The 1-6 output pad OP1-6 may be adjacent to the 1-5 output pad OP1-5 in the first direction DR1.

The 1-7 output pad OP1-7 may be adjacent to the 1-8 output pad OP1-8 in the direction opposite to the first direction DR1. The 1-8 output pad OP1-8 may be adjacent to the 1-9 output pad OP1-9 in the direction opposite to the first direction DR1. The 1-9 output pad OP1-9 may be adjacent to the 1-10 output pad OP1-10 in the direction opposite to the first direction DR1. The 1-10 output pad OP1-10 may be adjacent to the 1-11 output pad OP1-11 in the direction opposite to the first direction DR1. The 1-11 output pad OP1-11 may be adjacent to the 1-12 output pad OP1-12 in the direction opposite to the first direction DR1.

For example, the plurality of first input pads 310 may include a 1-1 input pad IP1-1, a 1-2 input pad IP1-2, a 1-3 input pad IP1-3, a 1-4 input pad IP1-4, a 1-5 input pad IP1-5, a 1-6 input pad IP1-6, a 1-7 input pad IP1-7, a 1-8 input pad IP1-8, a 1-9 input pad IP1-9, a 1-10 input pad IP1-10, a 1-11 input pad IP1-11, and a 1-12 input pad IP1-12.

The 1-2 input pad IP1-2 may be adjacent to the 1-1 input pad IP1-1 in the first direction DR1. The 1-2 input pad IP1-3 may be adjacent to the 1-2 input pad IP1-2 in the first direction DR1. The 1-4 input pad IP1-4 may be adjacent to the 1-3 input pad IP1-3 in the first direction DR1. The 1-5 input pad IP1-5 may be adjacent to the 1-4 input pad IP1-4 in the first direction DR1. The 1-6 input pad IP1-6 may be adjacent to the 1-5 input pad IP1-5 in the first direction DR1.

The 1-7 input pad IP1-7 may be adjacent to the 1-8 input pad IP1-8 in the direction opposite to the first direction DR1. The 1-8 input pad IP1-8 may be adjacent to the 1-9 input pad IP1-9 in the direction opposite to the first direction DR1. The 1-9 input pad IP1-9 may be adjacent to the 1-10 input pad IP1-10 in the direction opposite to the first direction DR1. The 1-10 input pad IP1-10 may be adjacent to the 1-11 input pad IP1-11 in the direction opposite to the first direction DR1. The 1-11 input pad IP1-11 may be adjacent to the 1-12 input pad IP1-12 in the direction opposite to the first direction DR1.

The 1-6 output pad OP1-6, the 1-7 output pad OP1-7, the 1-6 input pad IP1-6, and the 1-7 input pad IP1-7 may be connected to the first driving chip IC1.

The 1-1 output pad OP1-1 and the 1-1 input pad IP1-1 may be connected to each other through a 1-1 line L1-1. For example, the 1-1 line L1-1 may extend in the second direction DR2.

The 1-2 output pad OP1-2 and the 1-2 input pad IP1-2 may be connected to each other through a 1-2 line L1-2. For example, the 1-2 line L1-2 may extend in the second direction DR2.

The 1-3 input pad IP1-3 may be connected to a 1-3 line L1-3. In addition, the 1-3 line L1-3 may be connected to the 1-2 line L1-2. That is, the 1-3 input pad IP1-3 may be connected to the 1-2 line L1-2 through the 1-3 line L1-3. For example, the 1-3 line L1-3 may include a first portion extending in the first direction DR1 and a second portion extending in the second direction DR2.

The 1-4 output pad OP1-4 and the 1-4 input pad IP1-4 may be connected to each other through a 1-4 line L1-4. For example, the 1-4 line L1-4 may extend in the second direction DR2.

The 1-9 output pad OP1-9 and the 1-9 input pad IP1-9 may be connected to each other through a 1-5 line L1-5. For example, the 1-5 line L1-5 may extend in the second direction DR2.

The 1-10 input pad OP1-10 may be connected to a 1-6 line L1-6. In addition, the 1-6 line L1-6 may be connected to a 1-7 line L1-7. That is, the 1-10 input pad IP1-10 may be connected to the 1-7 line L1-7 through the 1-6 line L1-6. For example, the 1-6 line L1-6 may include a first portion extending in the first direction DR1 and a second portion extending in the second direction DR2.

The 1-11 output pad OP1-11 and the 1-11 input pad OP1-11 may be connected to a 1-7 line L1-7. For example, the 1-7 line L1-7 may extend in the second direction DR2.

The 1-12 output pad OP1-12 and the 1-12 input pad IP1-12 may be connected through a 1-8 line L1-8. For example, the 1-8 line L1-8 may extend in the second direction DR2.

For example, a plurality of first circuit board pads 410 may include a 1-1 circuit board pad FP1-1, a 1-2 circuit board pad FP1-2, a 1-3 circuit board pad FP1-3, a 1-4 circuit board pad FP1-4, a 1-5 circuit board pad FP1-5, a 1-6 circuit board pad FP1-6, a 1-7 circuit board pad FP1-7, a 1-8 circuit board pad FP1-8, a 1-9 circuit board pad FP1-9, a 1-10 circuit board pad FP1-10, a 1-11 circuit board pad FP1-11, and a 1-12 circuit board pad FP1-12.

The 1-2 circuit board pad FP1-2 may be adjacent to the 1-1 circuit board pad FP1-1 in the first direction DR1. The 1-3 circuit board pad FP1-3 may be adjacent to the 1-2 circuit board pad FP1-2 in the first direction DR1. The 1-4 circuit board pad FP1-4 may be adjacent to the 1-3 circuit board pad FP1-3 in the first direction DR1. The 1-5 circuit board pad FP1-5 may be adjacent to the 1-4 circuit board pad FP1-4 in the first direction DR1. The 1-6 circuit board pad FP1-6 may be adjacent to the 1-5 circuit board pad FP1-5 in the first direction DR1.

The 1-7 circuit board pad FP1-7 may be adjacent to the 1-8 circuit board pad FP1-8 in the direction opposite to the first direction DR1. The 1-8 circuit board pad FP1-8 may be adjacent to the 1-9 circuit board pad FP1-9 in the direction opposite to the first direction DR1. The 1-9 circuit board pad FP1-9 may be adjacent to the 1-1 circuit board pad FP1-10 in the direction opposite to the first direction DR1. The 1-10 circuit board pad FP1-10 may be adjacent to the 1-11 circuit board pad FP1-11 in the direction opposite to the first direction DR1. The 1-11 circuit board pad FP1-11 may be adjacent to the 1-12 circuit board pad FP1-12 in the direction opposite to the first direction DR1.

For example, the first test pads 510 may include a 1-1 test pad TP1-1, a 1-2 test pad TP1-2, a 1-3 test pad TP1-3, and a 1-4 test pad TP1-4.

For example, the second test pads 520 may include a 1-5 test pad TP1-5, a 1-6 test pad TP1-6, a 1-7 test pad TP1-7, and a 1-8 test pad TP1-8.

The 1-1 circuit board pad FP1-1 and the 1-1 test pad TP1-1 may be connected through a 1-1 test line TL1-1. For example, the 1-1 test line TL1-1 may extend in the second direction DR2.

The 1-2 circuit board pad FP1-2 and the 1-2 test pad TP1-2 may be connected through a 1-2 test line TL1-2. For example, the 1-2 test line TL1-2 may extend in the second direction DR2.

The 1-3 circuit board pad FP1-3 and the 1-3 test pad TP1-3 may be connected through a 1-3 test line TL1-3. For example, the 1-3 test line TL1-3 may extend in the second direction DR2.

The 1-4 circuit board pad FP1-4 and the 1-4 test pad TP1-4 may be connected through a 1-4 test line TL1-4. For example, the 1-4 test line TL1-4 may extend in the second direction DR2.

The 1-9 circuit board pad FP1-9 and the 1-5 test pad TP1-5 may be connected through a 1-5 test line TL1-5. For example, the 1-5 test line TL1-5 may extend in the second direction DR2.

The 1-10 circuit board pad FP1-10 and the 1-6 test pad TP1-6 may be connected through a 1-6 test line TL1-6. For example, the 1-6 test line TL1-6 may extend in the second direction DR2.

The 1-11 circuit board pad FP1-11 and the 1-7 test pad TP1-7 may be connected through a 1-7 test line TL1-7. For example, the 1-7 test line TL1-7 may extend in the second direction DR2.

The 1-12 circuit board pad FP1-12 and the 1-8 test pad TP1-8 may be connected through a 1-8 test line TL1-8. For example, the 1-8 test line TL1-8 may extend in the second direction DR2.

Referring to FIGS. 4 and 6, for example, a plurality of second substrate pads 120 may include a 2-1 substrate pad PP2-1, a 2-2 substrate pad PP2-2, a 2-3 substrate pad PP2-3, a 2-4 substrate pad PP2-4, a 2-5 substrate pad PP2-5, a 2-6 substrate pad PP2-6, a 2-7 substrate pad PP2-7, a 2-8 substrate pad PP2-8, a 2-9 substrate pad PP2-9, a 2-10 substrate pad PP2-10, a 2-11 substrate pad PP2-11, and a 2-12 substrate pad PP2-12.

The 2-2 substrate pad PP2-2 may be adjacent to the 2-1 substrate pad PP2-1 in the first direction DR1. The 2-3 substrate pad PP2-3 may be adjacent to the 2-2 substrate pad PP2-2 in the first direction DR1. The 2-4 substrate pad PP2-4 may be adjacent to the 2-3 substrate pad PP2-3 in the first direction DR1. The 2-5 substrate pad PP2-5 may be adjacent to the 2-4 substrate pad PP2-4 in the first direction DR1. The 2-6 substrate pad PP2-6 may be adjacent to the 2-5 substrate pad PP2-5 in the first direction DR1.

The 2-7 substrate pad PP2-7 may be adjacent to the 2-8 substrate pad PP2-8 in the direction opposite to the first direction DR1. The 2-8 substrate pad PP2-8 may be adjacent to the 2-9 substrate pad PP2-9 in the direction opposite to the first direction DR1. The 2-9 substrate pad PP2-9 may be adjacent to the 2-10 substrate pad PP2-10 in the direction opposite to the first direction DR1. The 2-10 substrate pad PP2-10 may be adjacent to the 2-11 substrate pad PP2-11 in the direction opposite to the first direction DR1. The 2-11 substrate pad PP2-11 may be adjacent to the 2-12 substrate pad PP2-12 in the direction opposite to the first direction DR1.

According to some embodiments, the 2-12 substrate pad PP2-12 may be connected to the anti-static wiring ESD. For example, the 2-12 substrate pad PP2-12 may be connected to other end of the anti-static wiring ESD.

As described above, the 1-1 substrate pad (e.g., the 1-1 substrate pad PP1-1 of FIG. 5) may be connected to the end of the anti-static wiring ESD. In addition, the 2-12 substrate pad PP2-12 may be connected to other end of the anti-static wiring ESD. Accordingly, a constant voltage may be applied from the first chip-on film COF1, the second chip-on film COF2, and the circuit board PCB to the anti-static wiring ESD. For example, a direct current (“DC”) voltage may be applied from the first chip-on film COF1, the second chip-on film COF2, and the circuit board PCB to the anti-static wiring ESD.

According to some embodiments, the 2-1 substrate pad PP2-1 and the 2-2 substrate pad PP2-2 may be connected to each other through a 2-1 bridge line BR2-1. In addition, the 2-2 substrate pad PP2-2 and the 2-4 substrate pad PP2-4 may be connected to each other through the 2-1 bridge line BR2-1. For example, the 2-1 substrate pad PP2-1 may be connected to the 2-1 bridge line BR2-1, the 2-2 substrate pad PP2-2 may be connected to the 2-1 bridge line BR2-1, and the 2-4 substrate pad PP2-4 may be connected to the 2-1 bridge line BR2-1.

According to some embodiments, the 2-1 bridge line BR2-1 may be located on the same layer as the 2-1 substrate pad PP2-1, the 2-2 substrate pad PP2-2, and the 2-4 substrate pad PP2-4. For example, the 2-1 substrate pad PP2-1, the 2-2 substrate pad PP2-2, and the 2-4 substrate pad PP2-4 may be located on the same layer as the source electrode (e.g., the source electrode SE of FIG. 3), and the 2-1 bridge line BR2-1 may also be located on the same layer as the source electrode.

However, embodiments according to the present disclosure are not limited thereto, and according to some embodiments, the 2-1 bridge line BR2-1 may be located on a different layer from the 2-1 substrate pad PP2-1, the 2-2 substrate pad PP2-2, and the 2-4 substrate pad PP2-4. In this case, the 2-1 bridge line BR2-1 may be connected to the 2-1 substrate pad PP2-1 by a seventh contact hole, may be connected to the 2-2 substrate pad PP2-2 by an eighth contact hole, and may be connected to the 2-4 substrate pad PP2-4 by a ninth contact hole.

According to some embodiments, the 2-9 substrate pad PP2-9 and the 2-11 substrate pad PP2-11 may be connected to each other through a 2-2 bridge line BR2-2. For example, the 2-9 substrate pad PP2-9 may be connected to the 2-2 bridge line BR2-2, and the 2-11 substrate pad PP2-11 may be connected to the 2-2 bridge line BR2-2.

According to some embodiments, the 2-2 bridge line BR2-2 may be located on the same layer as the 2-9 substrate pad PP2-9 and the 2-11 substrate pad PP2-11. For example, the 2-9 substrate pad PP2-9 and the 2-11 substrate pad PP2-11 may be located on the same layer as the source electrode, and the 2-2 bridge line BR2-2 may also be located on the same layer as the source electrode.

However, embodiments according to the present disclosure are not limited thereto, and according to some embodiments, the 2-2 bridge line BR2-2 may be located on a different layer from the 2-9 substrate pad PP2-9 and the 2-11 substrate pad PP2-11. In this case, the 2-2 bridge line BR2-2 may be connected to the 2-9 substrate pad PP2-9 by a tenth contact hole, and may be connected to the 2-11 substrate pad PP2-11 by an eleventh contact hole.

According to some embodiments, the 2-2 bridge line BR2-2 may be connected to the anti-static wiring ESD. According to some embodiments, the 2-2 bridge line BR2-2 may be located on a different layer from the anti-static wiring ESD. For example, the anti-static wiring ESD may be located on the same layer as the lower metal layer (e.g., the lower metal layer BML of FIG. 3), and the 2-2 bridge line BR2-2 may be located on the same layer as the source electrode. In this case, the 2-2 bridge line BR2-2 may be connected to the anti-static wiring ESD by a twelfth contact hole.

However, embodiments according to the present disclosure are not limited thereto, and according to some embodiments, the 2-2 bridge line BR2-2 may be located on the same layer as the anti-static wiring ESD.

For example, the plurality of second output pads 220 may include a 2-1 output pad OP2-1, a 2-2 output pad OP2-2, a 2-3 output pad OP2-3, a 2-4 output pad OP2-4, a 2-5 output pad OP2-5, a 2-6 output pad OP2-6, a 2-7 output pad OP2-7, a 2-8 output pad OP2-8, a 2-9 output pad OP2-9, a 2-10 output pad OP2-10, a 2-11 output pad OP2-11, and a 2-12 output pad OP2-12.

The 2-2 output pad OP2-2 may be adjacent to the 2-1 output pad OP2-1 in the first direction DR1. The 2-3 output pad OP2-3 may be adjacent to the 2-2 output pad OP2-2 in the first direction DR1. The 2-4 output pad OP2-4 may be adjacent to the 2-3 output pad OP2-3 in the first direction DR1. The 2-5 output pad OP2-5 may be adjacent to the 2-4 output pad OP2-4 in the first direction DR1. The 2-6 output pad OP2-6 may be adjacent to the 2-5 output pad OP2-5 in the first direction DR1.

The 2-7 output pad OP2-7 may be adjacent to the 2-8 output pad OP2-8 in the direction opposite to the first direction DR1. The 2-8 output pad OP2-8 may be adjacent to the 2-9 output pad OP2-9 in the direction opposite to the first direction DR1. The 2-9 output pad OP2-9 may be adjacent to the 2-10 output pad OP2-10 in the direction opposite to the first direction DR1. The 2-10 output pad OP2-10 may be adjacent to the 2-11 output pad OP2-11 in the direction opposite to the first direction DR1. The 2-11 output pad OP2-11 may be adjacent to the 2-12 output pad OP2-12 in the direction opposite to the first direction DR1.

For example, the plurality of second input pads 320 may include a 2-1 input pad IP2-1, a 2-2 input pad IP2-2, a 2-3 input pad IP2-3, a 2-4 input pad IP2-4, a 2-5 input pad IP2-5, a 2-6 input pad IP2-6, a 2-7 input pad IP2-7, a 2-8 input pad IP2-8, a 2-9 input pad IP2-9, a 2-10 input pad IP2-10, a 2-11 input pad IP2-11, and a 2-12 input pad IP2-12.

The 2-2 input pad IP2-2 may be adjacent to the 2-1 input pad IP2-1 in the first direction DR1. The 2-3 input pad IP2-3 may be adjacent to the 2-2 input pad IP2-2 in the first direction DR1. The 2-4 input pad IP2-4 may be adjacent to the 2-3 input pad IP2-3 in the first direction DR1. The 2-5 input pad IP2-5 may be adjacent to the 2-4 input pad IP2-4 in the first direction DR1. The 2-6 input pad IP2-6 may be adjacent to the 2-5 input pad IP2-5 in the first direction DR1.

The 2-7 input pad IP2-7 may be adjacent to the 2-8 input pad IP2-8 in the direction opposite to the first direction DR1. The 2-8 input pad IP2-8 may be adjacent to the 2-9 input pad IP2-9 in the direction opposite to the first direction DR1. The 2-9 input pad IP2-9 may be adjacent to the 2-10 input pad IP2-10 in the direction opposite to the first direction DR1. The 2-10 input pad IP2-10 may be adjacent to the 2-11 input pad IP2-11 in the direction opposite to the first direction DR1. The 2-11 input pad IP2-11 may be adjacent to the 2-12 input pad IP2-12 in the direction opposite to the first direction DR1.

The 2-6 output pad OP2-6, the 2-7 output pad OP2-7, the 2-6 input pad IP2-6, and the 2-7 input pad IP2-7 may be connected to the second driving chip IC2.

The 2-1 output pad OP2-1 and the 2-1 input pad IP2-1 may be connected to each other through a 2-1 line L2-1. For example, the 2-1 line L2-1 may extend in the second direction DR2.

The 2-2 output pad OP2-2 and the 2-2 input pad IP2-2 may be connected to each other through a 2-2 line L2-2. For example, the 2-2 line L2-2 may extend in the second direction DR2.

The 2-3 input pad IP2-3 may be connected to a 2-3 line L2-3. In addition, the 2-3 line L2-3 may be connected to the 2-2 line L2-2. That is, the 2-3 input pad IP2-3 may be connected to the 2-2 line L2-2 through the 2-3 line L2-3. For example, the 2-3 line L2-3 may include a first portion extending in the first direction DR1 and a second portion extending in the second direction DR2.

The 2-4 output pad OP2-4 and the 2-4 input pad IP2-4 may be connected to each other through a 2-4 line L2-4. For example, the 2-4 line L2-4 may extend in the second direction DR2.

The 2-9 output pad OP2-9 and the 2-9 input pad IP2-9 may be connected to each other through a 2-5 line L2-5. For example, the 2-5 line L2-5 may extend in the second direction DR2.

The 2-10 input pad IP2-10 may be connected to a 2-6 line L2-6. In addition, the 2-6 line L2-6 may be connected to a 2-7 line L2-7. That is, the 2-10 input pad IP2-10 may be connected to the 2-7 line L2-7 through the 2-6 line L2-6. For example, the 2-6 line L2-6 may include a first portion extending in the first direction DR1 and a second portion extending in the second direction DR2.

The 2-11 output pad OP2-11 and the 2-11 input pad IP2-11 may be connected to each other through a 2-7 line L2-7. For example, the 2-7 line L2-7 may extend in the second direction DR2.

The 2-12 output pad OP2-12 and the 2-12 input pad IP2-12 may be connected to each other through a 2-8 line L2-8. For example, the 2-8 line L2-8 may extend in the second direction DR2.

For example, a plurality of second circuit board pads 420 may include a 2-1 circuit board pad FP2-1, a 2-2 circuit board pad FP2-2, a 2-3 circuit board pad FP2-3, a 2-4 circuit board pad FP2-4, a 2-5 circuit board pad FP2-5, a 2-6 circuit board pad FP2-6, a 2-7 circuit board pad FP2-7, a 2-8 circuit board pad FP2-8, a 2-9 circuit board pad FP2-9, a 2-10 circuit board pad FP2-10, a 2-11 circuit board pad FP2-11, and a 2-12 circuit board pad FP2-12.

The 2-2 circuit board pad FP2-2 may be adjacent to the 2-1 circuit board pad FP2-1 in the first direction DR1. The 2-3 circuit board pad FP2-3 may be adjacent to the 2-2 circuit board pad FP2-2 in the first direction DR1. The 2-4 circuit board pad FP2-4 may be adjacent to the 2-3 circuit board pad FP2-3 in the first direction DR1. The 2-5 circuit board pad FP2-5 may be adjacent to the 2-4 circuit board pad FP2-4 in the first direction DR1. The 2-6 circuit board pad FP2-6 may be adjacent to the 2-5 circuit board pad FP2-5 in the first direction DR1.

The 2-7 circuit board pad FP2-7 may be adjacent to the 2-8 circuit board pad FP2-8 in the direction opposite to the first direction DR1. The 2-8 circuit board pad FP2-8 may be adjacent to the 2-9 circuit board pad FP2-9 in the direction opposite to the first direction DR1. The 2-9 circuit board pad FP2-9 may be adjacent to the 2-10 circuit board pad FP2-10 in the direction opposite to the first direction DR1. The 2-10 circuit board pad FP2-10 may be adjacent to the 2-11 circuit board pad FP2-11 in the direction opposite to the first direction DR1. The 2-11 circuit board pad FP2-11 may be adjacent to the 2-12 circuit board pad FP2-12 in the direction opposite to the first direction DR1.

For example, the third test pads 530 may include a 2-1 test pad TP2-1, a 2-2 test pad TP2-2, a 2-3 test pad TP2-3, and a 2-4 test pad TP2-4.

For example, the fourth test pads 540 may include a 2-5 test pad TP2-5, a 2-6 test pad TP2-6, a 2-7 test pad TP2-7, and a 2-8 test pad TP2-8.

The 2-1 circuit board pad FP2-1 and the 2-1 test pad TP2-1 may be connected to each other through a 2-1 test line TL2-1. For example, the 2-1 test line TL2-1 may extend in the second direction DR2.

The 2-2 circuit board pad FP2-2 and the 2-2 test pad TP2-2 may be connected to each other through a 2-2 test line TL2-2. For example, the 2-2 test line TL2-2 may extend in the second direction DR2.

The 2-3 circuit board pad FP2-3 and the 2-3 test pad TP2-3 may be connected to each other through a 2-3 test line TL2-3. For example, the 2-3 test line TL2-3 may extend in the second direction DR2.

The 2-4 circuit board pad FP2-4 and the 2-4 test pad TP2-4 may be connected to each other through a 2-4 test line TL2-4. For example, the 2-4 test line TL2-4 may extend in the second direction DR2.

The 2-9 circuit board pad FP2-9 and the 2-5 test pad TP2-5 may be connected to each other through a 2-5 test line TL2-5. For example, the 2-5 test line TL2-5 may extend in the second direction DR2.

The 2-10 circuit board pad FP2-10 and the 2-6 test pad TP2-6 may be connected to each other through a 2-6 test line TL2-6. For example, the 2-6 test line TL2-6 may extend in the second direction DR2.

The 2-11 circuit board pad FP2-11 and the 2-7 test pad TP2-7 may be connected to each other through a 2-7 test line TL2-7. For example, the 2-7 test line TL2-7 may extend in the second direction DR2.

The 2-12 circuit board pad FP2-12 and the 2-8 test pad TP2-7 may be connected to each other through a 2-8 test line TL2-8. For example, the 2-8 test line TL2-8 may extend in the second direction DR2.

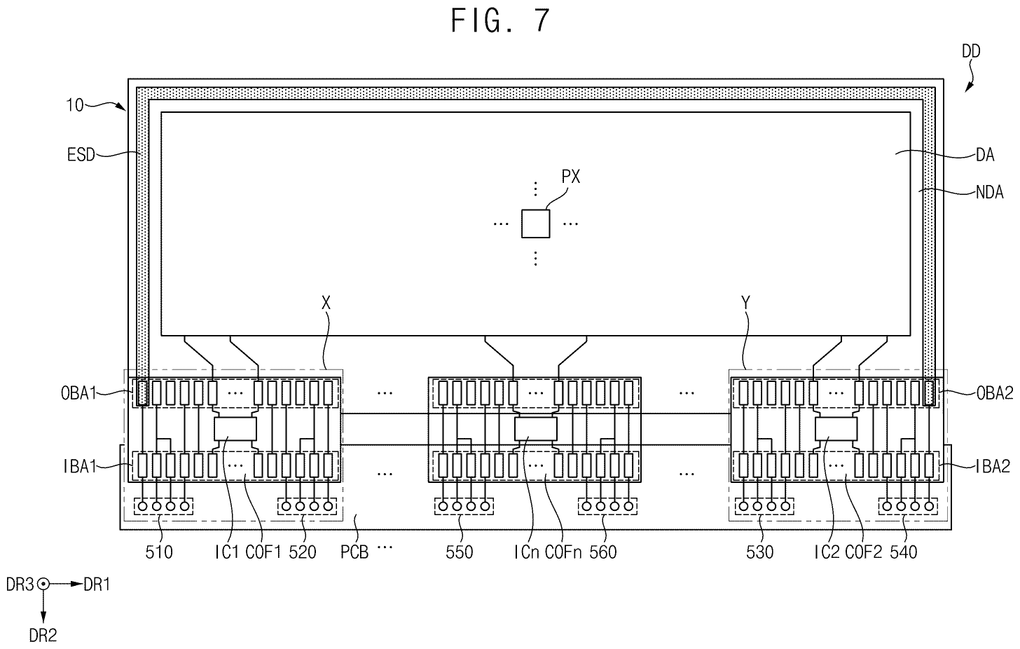

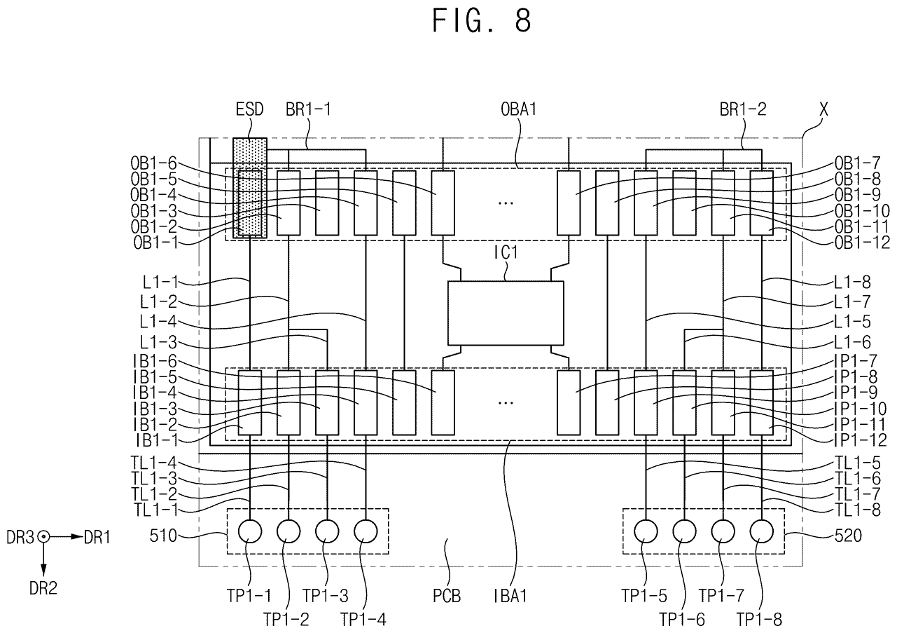

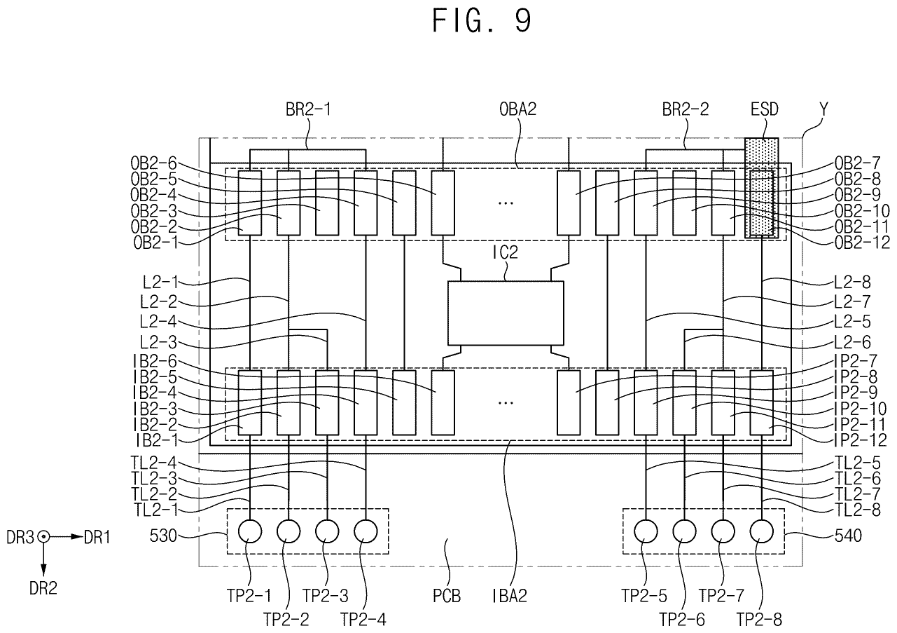

FIG. 7 is a plan view illustrating the display device of FIG. 1. FIG. 8 is an enlarged plan view of portion X of FIG. 7. FIG. 9 is an enlarged plan view of portion Y of FIG. 7. For example, FIG. 7 is a plan view illustrating that the substrate is bonded to the plurality of chip-on films and the plurality of chip-on films are bonded to the circuit board in FIG. 4.

Referring to FIGS. 4 and 7, the substrate 10 and the first chip-on film COF1 may be bonded to each other. For example, the plurality of first substrate pads (e.g., the plurality of first substrate pads 110 of FIG. 5) and the plurality of first output pads 210 may overlap in the plan view, so that the substrate 10 and the first chip-on film COF1 may be bonded to each other. For example, the plurality of first substrate pads and the plurality of first output pads 210 may be bonded to each other through an anisotropic conductive film (“ACF”). For example, a first output bonding area OBA1 in which the plurality of first substrate pads and the plurality of first output pads 210 overlap in the plan view may be defined.
the substrate 10 and the second chip-on film COF2 may be bonded to each other. For example, the plurality of second substrate pads (e.g., the plurality of second substrate pads 120 of FIG. 6) and the plurality of second output pads 220 may overlap in the plan view, so that the substrate 10 and the second chip-on film COF2 may be bonded to each other. For example, the plurality of second substrate pads and the plurality of second output pads 220 may be bonded to each other through an anisotropic conductive film (“ACF”). For example, a second output bonding area OBA2 in which the plurality of second substrate pads and the plurality of second output pads 220 overlap in the plan view may be defined.

The substrate 10 and the nth chip-on film COFn may be bonded to each other. The substrate 10 and the nth chip on-film COFn may be bonded to each other in substantially the same manner as the method in which the substrate 10 and the first chip-on film COF1 are bonded to each other.

The first chip-on film COF1 and the circuit board PCB may be bonded to each other. For example, the plurality of first input pads 310 and the plurality of first circuit board pads (e.g., the plurality of first circuit board pads 410 of FIG. 5) overlap in the plan view, so that the first chip-on film COF1 and the circuit board PCB may be bonded to each other. For example, the plurality of first input pads 310 and the plurality of first circuit board pads may be bonded to each other through an anisotropic conductive film. For example, a first input bonding area IBA1 in which the plurality of first input pads 310 and the plurality of first circuit board pads overlap in the plan view may be defined.

The second chip-on film COF2 and the circuit board PCB may be bonded to each other. For example, the plurality of second input pads 320 and the plurality of second circuit board pads (e.g., the plurality of second circuit board pads 420 of FIG. 6) overlap in the plan view, so that the second chip-on film COF2 and the circuit board PCB may be bonded to each other. For example, the plurality of second input pads 320 and the plurality of second circuit board pads may be bonded to each other through an anisotropic conductive film. For example, a second input bonding area IBA2 in which the plurality of second input pads 320 and the plurality of second circuit board pads overlap in the plan view may be defined.

The nth chip-on film COFn and the circuit board PCB may be bonded to each other. The nth chip-on film COFn and the circuit board PCB may be bonded to each other in substantially the same manner as the method in which the first chip-on film COF1 and the circuit board PCB are bonded to each other.

Referring to FIGS. 5 and 8, the first output bonding area OBA1 may include a 1-1 output bonding part OB1-1, a 1-2 output bonding part OB1-2, a 1-3 output bonding part OB1-3, a 1-4 output bonding part OB1-4, a 1-5 output bonding part OB1-5, a 1-6 output bonding part OB1-6, a 1-7 output bonding part OB1-7, a 1-8 output bonding part OB1-8, a 1-9 output bonding part OB1-9, a 1-10 output bonding part OB1-10, a 1-11 output bonding part OB1-11, and a 1-12 output bonding part OB1-12.

The 1-1 output bonding part OB1-1 may be defined by overlapping the 1-1 substrate pad PP1-1 and the 1-1 output pad OP1-1 in the plan view. For example, the 1-1 output bonding part OB1-1 may include the 1-1 substrate pad PP1-1, the 1-1 output pad OP1-1, and a 1-1 anisotropic conductive film located between the 1-1 substrate pad PP1-1 and the 1-1 output pad OP1-1. For example, the 1-1 substrate pad PP1-1 may be connected to the 1-1 output pad OP1-1 through the 1-1 anisotropic conductive film.

The 1-2 output bonding part OB1-2 may be defined by overlapping the 1-2 substrate pad PP1-2 and the 1-2 output pad OP1-2 in the plan view. For example, the 1-2 output bonding part OB1-2 may include the 1-2 substrate pad PP1-2, the 1-2 output pad OP1-2, and a 1-2 anisotropic conductive film located between the 1-2 substrate pad PP1-2 and the 1-2 output pad OP1-2. For example, the 1-2 substrate pad PP1-2 may be connected to the 1-2 output pad OP1-2 through the 1-2 anisotropic conductive film.

The 1-3 output bonding part OB1-3 may be defined by overlapping the 1-3 substrate pad PP1-3 and the 1-3 output pad OP1-3 in the plan view. For example, the 1-3 output bonding part OB1-3 may include the 1-3 substrate pad PP1-3, the 1-3 output pad OP1-3, and a 1-3 anisotropic conductive film located between the 1-3 substrate pad PP1-3 and the 1-3 output pad OP1-3. For example, the 1-3 substrate pad PP1-3 may be connected to the 1-3 output pad OP1-3 through the 1-3 anisotropic conductive film.

The 1-4 output bonding part OB1-4 may be defined by overlapping the 1-4 substrate pad PP1-4 and the 1-4 output pad OP1-4 in the plan view. For example, the 1-4 output bonding part OB1-4 may include the 1-4 substrate pad PP1-4, the 1-4 output pad OP1-4, and a 1-4 anisotropic conductive film located between the 1-4 substrate pad PP1-4 and the 1-4 output pad OP1-4. For example, the 1-4 substrate pad PP1-4 may be connected to the 1-4 output pad OP1-4 through the 1-4 anisotropic conductive film.

The 1-5 output bonding part OB1-5 may be defined by overlapping the 1-5 substrate pad PP1-5 and the 1-5 output pad OP1-5 in the plan view. For example, the 1-5 output bonding part OB1-5 may include the 1-5 substrate pad PP1-5, the 1-5 output pad OP1-5, and a 1-5 anisotropic conductive film located between the 1-5 substrate pad PP1-5 and the 1-5 output pad OP1-5. For example, the 1-5 substrate pad PP1-5 may be connected to the 1-5 output pad OP1-5 through the 1-5 anisotropic conductive film.

The 1-6 output bonding part OB1-6 may be defined by overlapping the 1-6 substrate pad PP1-6 and the 1-6 output pad OP1-6 in the plan view. For example, the 1-6 output bonding part OB1-6 may include the 1-6 substrate pad PP1-6, the 1-6 output pad OP1-6, and a 1-6 anisotropic conductive film located between the 1-6 substrate pad PP1-6 and the 1-6 output pad OP1-6. For example, the 1-6 substrate pad PP1-6 may be connected to the 1-6 output pad OP1-6 through the 1-6 anisotropic conductive film.

The 1-7 output bonding part OB1-7 may be defined by overlapping the 1-7 substrate pad PP1-7 and the 1-7 output pad OP1-7 in the plan view. For example, the 1-7 output bonding part OB1-7 may include the 1-7 substrate pad PP1-7, the 1-7 output pad OP1-7, and a 1-7 anisotropic conductive film located between the 1-7 substrate pad PP1-7 and the 1-7 output pad OP1-7. For example, the 1-7 substrate pad PP1-7 may be connected to the 1-7 output pad OP1-7 through the 1-7 anisotropic conductive film.

The 1-8 output bonding part OB1-8 may be defined by overlapping the 1-8 substrate pad PP1-8 and the 1-8 output pad OP1-8 in the plan view. For example, the 1-8 output bonding part OB1-8 may include the 1-8 substrate pad PP1-8, the 1-8 output pad OP1-8, and a 1-8 anisotropic conductive film located between the 1-8 substrate pad PP1-8 and the 1-8 output pad OP1-8. For example, the 1-8 substrate pad PP1-8 may be connected to the 1-8 output pad OP1-8 through the 1-8 anisotropic conductive film.

The 1-9 output bonding part OB1-9 may be defined by overlapping the 1-9 substrate pad PP1-9 and the 1-9 output pad OP1-9 in the plan view. For example, the 1-9 output bonding part OB1-9 may include the 1-9 substrate pad PP1-9, the 1-9 output pad OP1-9, and a 1-9 anisotropic conductive film located between the 1-9 substrate pad PP1-9 and the 1-9 output pad OP1-9. For example, the 1-9 substrate pad PP1-9 may be connected to the 1-9 output pad OP1-9 through the 1-9 anisotropic conductive film.

The 1-10 output bonding part OB1-10 may be defined by overlapping the 1-10 substrate pad PP1-10 and the 1-10 output pad OP1-10 in the plan view. For example, the 1-10 output bonding part OB1-10 may include the 1-10 substrate pad PP1-10, the 1-10 output pad OP1-10, and a 1-10 anisotropic conductive film located between the 1-10 substrate pad PP1-10 and the 1-10 output pad OP1-10. For example, the 1-10 substrate pad PP1-10 may be connected to the 1-10 output pad OP1-10 through the 1-10 anisotropic conductive film.

The 1-11 output bonding part OB1-11 may be defined by overlapping the 1-11 substrate pad PP1-11 and the 1-11 output pad OP1-11 in the plan view. For example, the 1-11 output bonding part OB1-11 may include the 1-11 substrate pad PP1-11, the 1-11 output pad OP1-11, and a 1-11 anisotropic conductive film located between the 1-11 substrate pad PP1-11 and the 1-11 output pad OP1-11. For example, the 1-11 substrate pad PP1-11 may be connected to the 1-11 output pad OP1-11 through the 1-11 anisotropic conductive film.

The 1-12 output bonding part OB1-12 may be defined by overlapping the 1-12 substrate pad PP1-12 and the 1-12 output pad OP1-12 in the plan view. For example, the 1-12 output bonding part OB1-12 may include the 1-12 substrate pad PP1-12, the 1-12 output pad OP1-12, and a 1-12 anisotropic conductive film located between the 1-12 substrate pad PP1-12 and the 1-12 output pad OP1-12. For example, the 1-12 substrate pad PP1-12 may be connected to the 1-12 output pad OP1-12 through the 1-12 anisotropic conductive film.

The first input bonding area IBA1 may include a 1-1 input bonding part IB1-1, a 1-2 input bonding part IB1-2, a 1-3 input bonding part IB1-3, a 1-4 input bonding part IB1-4, a 1-5 input bonding part IB1-5, a 1-6 input bonding part IB1-6, a 1-7 input bonding part IB1-7, a 1-8 input bonding part IB1-8, a 1-9 input bonding part IB1-9, a 1-10 input bonding part IB1-10, a 1-11 input bonding part IB1-11, and a 1-12 input bonding part IB1-12.

The 1-1 input bonding part IB1-1 may be defined by overlapping the 1-1 input pad IP1-1 and the 1-1 circuit board pad FP1-1 in the plan view. For example, the 1-1 input bonding part IB1-1 may include the 1-1 input pad IP1-1, the 1-1 circuit board pad FP1-1, and a 1-13 anisotropic conductive film located between the 1-1 input pad IP1-1 and the 1-1 circuit board pad FP1-1. For example, the 1-1 circuit board pad FP1-1 may be connected to the 1-1 input pad IP1-1 through the 1-13 anisotropic conductive film.

The 1-2 input bonding part IB1-2 may be defined by overlapping the 1-2 input pad IP1-2 and the 1-2 circuit board pad FP1-2 in the plan view. For example, the 1-2 input bonding part IB1-2 may include the 1-2 input pad IP1-2, the 1-2 circuit board pad FP1-2, and a 1-14 anisotropic conductive film located between the 1-2 input pad IP1-2 and the 1-2 circuit board pad FP1-2. For example, the 1-2 circuit board pad FP1-2 may be connected to the 1-2 input pad IP1-2 through the 1-14 anisotropic conductive film.

The 1-3 input bonding part IB1-3 may be defined by overlapping the 1-3 input pad IP1-3 and the 1-3 circuit board pad FP1-3 in the plan view. For example, the 1-3 input bonding part IB1-3 may include the 1-3 input pad IP1-3, the 1-3 circuit board pad FP1-3, and a 1-15 anisotropic conductive film located between the 1-3 input pad IP1-3 and the 1-3 circuit board pad FP1-3. For example, the 1-3 circuit board pad FP1-3 may be connected to the 1-3 input pad IP1-3 through the 1-15 anisotropic conductive film.

The 1-4 input bonding part IB1-4 may be defined by overlapping the 1-4 input pad IP1-4 and the 1-4 circuit board pad FP1-4 in the plan view. For example, the 1-4 input bonding part IB1-4 may include the 1-4 input pad IP1-4, the 1-4 circuit board pad FP1-4, and a 1-16 anisotropic conductive film located between the 1-4 input pad IP1-4 and the 1-4 circuit board pad FP1-4. For example, the 1-4 circuit board pad FP1-4 may be connected to the 1-4 input pad IP1-4 through the 1-16 anisotropic conductive film.

The 1-5 input bonding part IB1-5 may be defined by overlapping the 1-5 input pad IP1-5 and the 1-5 circuit board pad FP1-5 in the plan view. For example, the 1-5 input bonding part IB1-5 may include the 1-5 input pad IP1-5, the 1-5 circuit board pad FP1-5, and a 1-17 anisotropic conductive film located between the 1-5 input pad IP1-5 and the 1-5 circuit board pad FP1-5. For example, the 1-5 circuit board pad FP1-5 may be connected to the 1-5 input pad IP1-5 through the 1-17 anisotropic conductive film.

The 1-6 input bonding part IB1-6 may be defined by overlapping the 1-6 input pad IP1-6 and the 1-6 circuit board pad FP1-6 in the plan view. For example, the 1-6 input bonding part IB1-6 may include the 1-6 input pad IP1-6, the 1-6 circuit board pad FP1-6, and a 1-18 anisotropic conductive film located between the 1-6 input pad IP1-6 and the 1-6 circuit board pad FP1-6. For example, the 1-6 circuit board pad FP1-6 may be connected to the 1-6 input pad IP1-6 through the 1-18 anisotropic conductive film.

The 1-7 input bonding part IB1-7 may be defined by overlapping the 1-7 input pad IP1-7 and the 1-7 circuit board pad FP1-7 in the plan view. For example, the 1-7 input bonding part IB1-7 may include the 1-7 input pad IP1-7, the 1-7 circuit board pad FP1-7, and a 1-19 anisotropic conductive film located between the 1-7 input pad IP1-7 and the 1-7 circuit board pad FP1-7. For example, the 1-7 circuit board pad FP1-7 may be connected to the 1-7 input pad IP1-7 through the 1-19 anisotropic conductive film.

The 1-8 input bonding part IB1-8 may be defined by overlapping the 1-8 input pad IP1-8 and the 1-8 circuit board pad FP1-8 in the plan view. For example, the 1-8 input bonding part IB1-8 may include the 1-8 input pad IP1-8, the 1-8 circuit board pad FP1-8, and a 1-20 anisotropic conductive film located between the 1-8 input pad IP1-8 and the 1-8 circuit board pad FP1-8. For example, the 1-8 circuit board pad FP1-8 may be connected to the 1-8 input pad IP1-8 through the 1-20 anisotropic conductive film.

The 1-9 input bonding part IB1-9 may be defined by overlapping the 1-9 input pad IP1-9 and the 1-9 circuit board pad FP1-9 in the plan view. For example, the 1-9 input bonding part IB1-9 may include the 1-9 input pad IP1-9, the 1-9 circuit board pad FP1-9, and a 1-21 anisotropic conductive film located between the 1-9 input pad IP1-9 and the 1-9 circuit board pad FP1-9. For example, the 1-9 circuit board pad FP1-9 may be connected to the 1-9 input pad IP1-9 through the 1-21 anisotropic conductive film.

The 1-10 input bonding part IB1-10 may be defined by overlapping the 1-10 input pad IP1-10 and the 1-10 circuit board pad FP1-10 in the plan view. For example, the 1-10 input bonding part IB1-10 may include the 1-10 input pad IP1-10, the 1-10 circuit board pad FP1-10, and a 1-22 anisotropic conductive film located between the 1-10 input pad IP1-10 and the 1-10 circuit board pad FP1-10. For example, the 1-10 circuit board pad FP1-10 may be connected to the 1-10 input pad IP1-10 through the 1-22 anisotropic conductive film.

The 1-11 input bonding part IB1-11 may be defined by overlapping the 1-11 input pad IP1-11 and the 1-11 circuit board pad FP1-11 in the plan view. For example, the 1-11 input bonding part IB1-11 may include the 1-11 input pad IP1-11, the 1-11 circuit board pad FP1-11, and a 1-23 anisotropic conductive film located between the 1-11 input pad IP1-11 and the 1-11 circuit board pad FP1-11. For example, the 1-11 circuit board pad FP1-11 may be connected to the 1-11 input pad IP1-11 through the 1-23 anisotropic conductive film.

The 1-12 input bonding part IB1-12 may be defined by overlapping the 1-12 input pad IP1-12 and the 1-12 circuit board pad FP1-12 in the plan view. For example, the 1-12 input bonding part IB1-12 may include the 1-12 input pad IP1-12, the 1-12 circuit board pad FP1-12, and a 1-24 anisotropic conductive film located between the 1-12 input pad IP1-12 and the 1-12 circuit board pad FP1-12. For example, the 1-12 circuit board pad FP1-12 may be connected to the 1-12 input pad IP1-12 through the 1-24 anisotropic conductive film.

According to some embodiments, the 1-3 output bonding part OB1-3 may be omitted. That is, the 1-3 substrate pad PP1-3 and the 1-3 output pad OP1-3 may be omitted. In addition, the 1-10 output bonding part OB1-10 may be omitted. That is, the 1-10 substrate pad PP1-10 and the 1-10 output pad OP1-10 may be omitted.

Hereinafter, a method of measuring resistance of the display device (for example, the display device DD of FIG. 7) according to some embodiments will be described.

A method of measuring resistance of the display device according to some embodiments may include measuring a resistance of the 1-2 output bonding part OB1-2 and the 1-11 output bonding part OB1-11 using a resistance tester including an ammeter and a voltmeter.

For example, the resistance tester may include an ammeter including a first terminal and a second terminal, and a voltmeter including a first terminal and a second terminal.

According to some embodiments, the first terminal of the ammeter may be connected to the 1-1 test pad TP1-1. In addition, the second terminal of the ammeter may be connected to the 1-2 test pad TP1-2. In addition, the first terminal of the voltmeter may be connected to the 1-3 test pad TP1-3. In addition, the second terminal of the voltmeter may be connected to the 1-4 test pad TP1-4.

When the ammeter flows a constant current, a circuit including the 1-1 test line TL1-1, the 1-1 input bonding part IB1-1, the 1-1 line L1-1, the 1-1 output bonding part OB1-1, the 1-1 bridge line BR1-1, the 1-2 line L1-2, the 1-2 input bonding part IB1-2 and the 1-2 test line TL1-2 may be formed. In this case, a resistance applied to the 1-2 output bonding part OB1-2 may be measured through the first terminal of the voltmeter connected to the 1-3 test pad TP1-3 and the second terminal of the voltmeter connected to the 1-4 test pad TP1-4.

According to some embodiments, the first terminal of the ammeter may be connected to the 1-8 test pad TP1-8. In addition, the second terminal of the ammeter may be connected to the 1-7 test pad TP1-7. In addition, the first terminal of the voltmeter may be connected to the 1-6 test pad TP1-6. In addition, the second terminal of the voltmeter may be connected to the 1-5 test pad TP1-5.

When the ammeter flows a constant current, a circuit including the 1-8 test line TL1-8, the 1-12 input bonding part IB1-12, the 1-8 line L1-8, the 1-12 output bonding part OB1-12, the 1-2 bridge line BR1-2, the 1-7 line L1-7, the 1-11 input bonding part IB1-11, and the 1-7 test line TL1-7 may be formed. In this case, a resistance applied to the 1-11 output bonding part OB1-11 may be measured through the first terminal of the voltmeter connected to the 1-6 test pad TP1-6 and the second terminal of the voltmeter connected to the 1-5 test pad TP1-5.

Referring to FIGS. 6 and 9, the second output bonding area OBA2 may include a 2-1 output bonding part OB2-1, a 2-2 output bonding part OB2-2, a 2-3 output bonding part OB2-3, a 2-4 output bonding part OB2-4, a 2-5 output bonding part OB2-5, a 2-6 output bonding part OB2-6, a 2-7 output bonding part OB2-7, a 2-8 output bonding part OB2-8, a 2-9 output bonding part OB2-9, a 2-10 output bonding part OB2-10, a 2-11 output bonding part OB2-11, and a 2-12 output bonding part OB2-12.

The 2-1 output bonding part OB2-1 may be defined by overlapping the 2-1 substrate pad PP2-1 and the 2-1 output pad OP2-1 in the plan view. For example, the 2-1 output bonding part OB2-1 may include the 2-1 substrate pad PP2-1, the 2-1 output pad OP2-1, and a 2-1 anisotropic conductive film located between the 2-1 substrate pad PP2-1 and the 2-1 output pad OP2-1. For example, the 2-1 substrate pad PP2-1 may be connected to the 2-1 output pad OP2-1 through the 2-1 anisotropic conductive film.

The 2-2 output bonding part OB2-2 may be defined by overlapping the 2-2 substrate pad PP2-2 and the 2-2 output pad OP2-2 in the plan view. For example, the 2-2 output bonding part OB2-2 may include the 2-2 substrate pad PP2-2, the 2-2 output pad OP2-2, and a 2-2 anisotropic conductive film located between the 2-2 substrate pad PP2-2 and the 2-2 output pad OP2-2. For example, the 2-2 substrate pad PP2-2 may be connected to the 2-2 output pad OP2-2 through the 2-2 anisotropic conductive film.

The 2-3 output bonding part OB2-3 may be defined by overlapping the 2-3 substrate pad PP2-3 and the 2-3 output pad OP2-3 in the plan view. For example, the 2-3 output bonding part OB2-3 may include the 2-3 substrate pad PP2-3, the 2-3 output pad OP2-3, and a 2-3 anisotropic conductive film located between the 2-3 substrate pad PP2-3 and the 2-3 output pad OP2-3. For example, the 2-3 substrate pad PP2-3 may be connected to the 2-3 output pad OP2-3 through the 2-3 anisotropic conductive film.

The 2-4 output bonding part OB2-4 may be defined by overlapping the 2-4 substrate pad PP2-4 and the 2-4 output pad OP2-4 in the plan view. For example, the 2-4 output bonding part OB2-4 may include the 2-4 substrate pad PP2-4, the 2-4 output pad OP2-4, and a 2-4 anisotropic conductive film located between the 2-4 substrate pad PP2-4 and the 2-4 output pad OP2-4. For example, the 2-4 substrate pad PP2-4 may be connected to the 2-4 output pad OP2-4 through the 2-4 anisotropic conductive film.

The 2-5 output bonding part OB2-5 may be defined by overlapping the 2-5 substrate pad PP2-5 and the 2-5 output pad OP2-5 in the plan view. For example, the 2-5 output bonding part OB2-5 may include the 2-5 substrate pad PP2-5, the 2-5 output pad OP2-5, and a 2-5 anisotropic conductive film located between the 2-5 substrate pad PP2-5 and the 2-5 output pad OP2-5. For example, the 2-5 substrate pad PP2-5 may be connected to the 2-5 output pad OP2-5 through the 2-5 anisotropic conductive film.

The 2-6 output bonding part OB2-6 may be defined by overlapping the 2-6 substrate pad PP2-6 and the 2-6 output pad OP2-6 in the plan view. For example, the 2-6 output bonding part OB2-6 may include the 2-6 substrate pad PP2-6, the 2-6 output pad OP2-6, and a 2-6 anisotropic conductive film located between the 2-6 substrate pad PP2-6 and the 2-6 output pad OP2-6. For example, the 2-6 substrate pad PP2-6 may be connected to the 2-6 output pad OP2-6 through the 2-6 anisotropic conductive film.

The 2-7 output bonding part OB2-7 may be defined by overlapping the 2-7 substrate pad PP2-7 and the 2-7 output pad OP2-7 in the plan view. For example, the 2-7 output bonding part OB2-7 may include the 2-7 substrate pad PP2-7, the 2-7 output pad OP2-7, and a 2-7 anisotropic conductive film located between the 2-7 substrate pad PP2-7 and the 2-7 output pad OP2-7. For example, the 2-7 substrate pad PP2-7 may be connected to the 2-7 output pad OP2-7 through the 2-7 anisotropic conductive film.

The 2-8 output bonding part OB2-8 may be defined by overlapping the 2-8 substrate pad PP2-8 and the 2-8 output pad OP2-8 in the plan view. For example, the 2-8 output bonding part OB2-8 may include the 2-8 substrate pad PP2-8, the 2-8 output pad OP2-8, and a 2-8 anisotropic conductive film located between the 2-8 substrate pad PP2-8 and the 2-8 output pad OP2-8. For example, the 2-8 substrate pad PP2-8 may be connected to the 2-8 output pad OP2-8 through the 2-8 anisotropic conductive film.

The 2-9 output bonding part OB2-9 may be defined by overlapping the 2-9 substrate pad PP2-9 and the 2-9 output pad OP2-9 in the plan view. For example, the 2-9 output bonding part OB2-9 may include the 2-9 substrate pad PP2-9, the 2-9 output pad OP2-9, and a 2-9 anisotropic conductive film located between the 2-9 substrate pad PP2-9 and the 2-9 output pad OP2-9. For example, the 2-9 substrate pad PP2-9 may be connected to the 2-9 output pad OP2-9 through the 2-9 anisotropic conductive film.

The 2-10 output bonding part OB2-10 may be defined by overlapping the 2-10 substrate pad PP2-10 and the 2-10 output pad OP2-10 in the plan view. For example, the 2-10 output bonding part OB2-10 may include the 2-10 substrate pad PP2-10, the 2-10 output pad OP2-10, and a 2-10 anisotropic conductive film located between the 2-10 substrate pad PP2-10 and the 2-10 output pad OP2-10. For example, the 2-10 substrate pad PP2-10 may be connected to the 2-10 output pad OP2-10 through the 2-10 anisotropic conductive film.

The 2-11 output bonding part OB2-11 may be defined by overlapping the 2-11 substrate pad PP2-11 and the 2-11 output pad OP2-11 in the plan view. For example, the 2-11 output bonding part OB2-11 may include the 2-11 substrate pad PP2-11, the 2-11 output pad OP2-11, and a 2-11 anisotropic conductive film located between the 2-11 substrate pad PP2-11 and the 2-11 output pad OP2-11. For example, the 2-11 substrate pad PP2-11 may be connected to the 2-11 output pad OP2-11 through the 2-11 anisotropic conductive film.

The 2-12 output bonding part OB2-12 may be defined by overlapping the 2-12 substrate pad PP2-12 and the 2-12 output pad OP2-12 in the plan view. For example, the 2-12 output bonding part OB2-12 may include the 2-12 substrate pad PP2-12, the 2-12 output pad OP2-12, and a 2-12 anisotropic conductive film located between the 2-12 substrate pad PP2-12 and the 2-12 output pad OP2-12. For example, the 2-12 substrate pad PP2-12 may be connected to the 2-12 output pad OP2-12 through the 2-12 anisotropic conductive film.

The second input bonding area IBA2 may include a 2-1 input bonding part IB2-1, a 2-2 input bonding part IB2-2, a 2-3 input bonding part IB2-3, a 2-4 input bonding part IB2-4, a 2-5 input bonding part IB2-5, a 2-6 input bonding part IB2-6, a 2-7 input bonding part IB2-7, a 2-8 input bonding part IB2-8, a 2-9 input bonding part IB2-9, a 2-10 input bonding part IB2-10, a 2-11 input bonding part IB2-11, and a 2-12 input bonding part IB2-12.

The 2-1 input bonding part IB2-1 may be defined by overlapping the 2-1 input pad IP2-1 and the 2-1 circuit board pad FP2-1 in the plan view. For example, the 2-1 input bonding part IB2-1 may include the 2-1 input pad IP2-1, the 2-1 circuit board pad FP2-1, and a 2-13 anisotropic conductive film located between the 2-1 input pad IP2-1 and the 2-1 circuit board pad FP2-1. For example, the 2-1 circuit board pad FP2-1 may be connected to the 2-1 input pad IP2-1 through the 2-13 anisotropic conductive film.

The 2-2 input bonding part IB2-2 may be defined by overlapping the 2-2 input pad IP2-2 and the 2-2 circuit board pad FP2-2 in the plan view. For example, the 2-2 input bonding part IB2-2 may include the 2-2 input pad IP2-2, the 2-2 circuit board pad FP2-2, and a 2-14 anisotropic conductive film located between the 2-2 input pad IP2-2 and the 2-2 circuit board pad FP2-2. For example, the 2-2 circuit board pad FP2-2 may be connected to the 2-2 input pad IP2-2 through the 2-14 anisotropic conductive film.

The 2-3 input bonding part IB2-3 may be defined by overlapping the 2-3 input pad IP2-3 and the 2-3 circuit board pad FP2-3 in the plan view. For example, the 2-3 input bonding part IB2-3 may include the 2-3 input pad IP2-3, the 2-3 circuit board pad FP2-3, and a 2-15 anisotropic conductive film located between the 2-3 input pad IP2-3 and the 2-3 circuit board pad FP2-3. For example, the 2-3 circuit board pad FP2-3 may be connected to the 2-3 input pad IP2-3 through the 2-15 anisotropic conductive film.

The 2-4 input bonding part IB2-4 may be defined by overlapping the 2-4 input pad IP2-4 and the 2-4 circuit board pad FP2-4 in the plan view. For example, the 2-4 input bonding part IB2-4 may include the 2-4 input pad IP2-4, the 2-4 circuit board pad FP2-4, and a 2-16 anisotropic conductive film located between the 2-4 input pad IP2-4 and the 2-4 circuit board pad FP2-4. For example, the 2-4 circuit board pad FP2-4 may be connected to the 2-4 input pad IP2-4 through the 2-16 anisotropic conductive film.

The 2-5 input bonding part IB2-5 may be defined by overlapping the 2-5 input pad IP2-5 and the 2-5 circuit board pad FP2-5 in the plan view. For example, the 2-5 input bonding part IB2-5 may include the 2-5 input pad IP2-5, the 2-5 circuit board pad FP2-5, and a 2-17 anisotropic conductive film located between the 2-5 input pad IP2-5 and the 2-5 circuit board pad FP2-5. For example, the 2-5 circuit board pad FP2-5 may be connected to the 2-5 input pad IP2-5 through the 2-17 anisotropic conductive film.

The 2-6 input bonding part IB2-6 may be defined by overlapping the 2-6 input pad IP2-6 and the 2-6 circuit board pad FP2-6 in the plan view. For example, the 2-6 input bonding part IB2-6 may include the 2-6 input pad IP2-6, the 2-6 circuit board pad FP2-6, and a 2-18 anisotropic conductive film located between the 2-6 input pad IP2-6 and the 2-6 circuit board pad FP2-6. For example, the 2-6 circuit board pad FP2-6 may be connected to the 2-6 input pad IP2-6 through the 2-18 anisotropic conductive film.

The 2-7 input bonding part IB2-7 may be defined by overlapping the 2-7 input pad IP2-7 and the 2-7 circuit board pad FP2-7 in the plan view. For example, the 2-7 input bonding part IB2-7 may include the 2-7 input pad IP2-7, the 2-7 circuit board pad FP2-7, and a 2-19 anisotropic conductive film located between the 2-7 input pad IP2-7 and the 2-7 circuit board pad FP2-7. For example, the 2-7 circuit board pad FP2-7 may be connected to the 2-7 input pad IP2-7 through the 2-19 anisotropic conductive film.

The 2-8 input bonding part IB2-8 may be defined by overlapping the 2-8 input pad IP2-8 and the 2-8 circuit board pad FP2-8 in the plan view. For example, the 2-8 input bonding part IB2-8 may include the 2-8 input pad IP2-8, the 2-8 circuit board pad FP2-8, and a 2-20 anisotropic conductive film located between the 2-8 input pad IP2-8 and the 2-8 circuit board pad FP2-8. For example, the 2-8 circuit board pad FP2-8 may be connected to the 2-8 input pad IP2-8 through the 2-20 anisotropic conductive film.

The 2-9 input bonding part IB2-9 may be defined by overlapping the 2-9 input pad IP2-9 and the 2-9 circuit board pad FP2-9 in the plan view. For example, the 2-9 input bonding part IB2-9 may include the 2-9 input pad IP2-9, the 2-9 circuit board pad FP2-9, and a 2-21 anisotropic conductive film located between the 2-9 input pad IP2-9 and the 2-9 circuit board pad FP2-9. For example, the 2-9 circuit board pad FP2-9 may be connected to the 2-9 input pad IP2-9 through the 2-21 anisotropic conductive film.

The 2-10 input bonding part IB2-10 may be defined by overlapping the 2-10 input pad IP2-10 and the 2-10 circuit board pad FP2-10 in the plan view. For example, the 2-10 input bonding part IB2-10 may include the 2-10 input pad IP2-10, the 2-10 circuit board pad FP2-10, and a 2-22 anisotropic conductive film located between the 2-10 input pad IP2-10 and the 2-10 circuit board pad FP2-10. For example, the 2-10 circuit board pad FP2-10 may be connected to the 2-10 input pad IP2-10 through the 2-22 anisotropic conductive film.

The 2-11 input bonding part IB2-11 may be defined by overlapping the 2-11 input pad IP2-11 and the 2-11 circuit board pad FP2-11 in the plan view. For example, the 2-11 input bonding part IB2-11 may include the 2-11 input pad IP2-11, the 2-11 circuit board pad FP2-11, and a 2-23 anisotropic conductive film located between the 2-11 input pad IP2-11 and the 2-11 circuit board pad FP2-11. For example, the 2-11 circuit board pad FP2-11 may be connected to the 2-11 input pad IP2-11 through the 2-23 anisotropic conductive film.

The 2-12 input bonding part IB2-12 may be defined by overlapping the 2-12 input pad IP2-12 and the 2-12 circuit board pad FP2-12 in the plan view. For example, the 2-12 input bonding part IB2-12 may include the 2-12 input pad IP2-12, the 2-12 circuit board pad FP2-12, and a 2-24 anisotropic conductive film located between the 2-12 input pad IP2-12 and the 2-12 circuit board pad FP2-12. For example, the 2-12 circuit board pad FP2-12 may be connected to the 2-12 input pad IP2-12 through the 2-24 anisotropic conductive film.

According to some embodiments, the 2-3 output bonding part OB2-3 may be omitted. That is, the 2-3 substrate pad PP2-3 and the 2-3 output pad OP2-3 may be omitted. In addition, the 2-10 output bonding part OB2-10 may be omitted. That is, the 2-10 substrate pad PP2-10 and the 2-10 output pad OP2-10 may be omitted.

The method of measuring resistance of the display device according to some embodiments may further include measuring a resistance of the 2-2 output bonding part OB2-2 and the 2-11 output bonding part OB2-11 using the resistance tester.

According to some embodiments, the first terminal of the ammeter may be connected to the 2-1 test pad TP2-1. In addition, the second terminal of the ammeter may be connected to the 2-1 test pad TP2-2. In addition, the first terminal of the voltmeter may be connected to the 2-3 test pad TP2-3. In addition, the second terminal of the voltmeter may be connected to the 2-4 test pad TP2-4.

When the ammeter flows a constant current, a circuit including the 2-1 test line TL2-1, the 2-1 input bonding part IB2-1, the 2-1 line L2-1, the 2-1 output bonding part OB2-1, the 2-1 bridge line BR2-1, the 2-2 line L2-2, the 2-2 input bonding part IB2-2 and the 2-2 test line TL2-2 may be formed. In this case, a resistance applied to the 2-2 output bonding part OB2-2 may be measured through the first terminal of the voltmeter connected to the 2-3 test pad TP2-3 and the second terminal of the voltmeter connected to the 2-4 test pad TP2-4.

According to some embodiments, the second terminal of the ammeter may be connected to the 2-8 test pad TP2-8. In addition, the second terminal of the ammeter may be connected to the 2-7 test pad TP2-7. In addition, the first terminal of the voltmeter may be connected to the 2-6 test pad TP2-6. In addition, the second terminal of the voltmeter may be connected to the 2-5 test pad TP2-5.

When the ammeter flows a constant current, a circuit including the 2-8 test line TL2-8, the 2-12 input bonding part IB2-12, the 2-8 line L2-8, the 2-12 output bonding part OB2-12, the 2-2 bridge line BR2-2, the 2-7 line L2-7, the 2-11 input bonding part IB2-11, and the 2-7 test line TL2-7 may be formed. In this case, a resistance applied to a 2-11 output bonding part OB2-11 may be measured through the first terminal of the voltmeter connected to the 2-6 test pad TP2-6 and the second terminal of the voltmeter connected to the 2-5 test pad TP2-5.

Referring to FIGS. 8 and 9, the voltage may be applied to the substrate (e.g., the substrate 10 of FIG. 7) through the anti-static wiring ESD through the 1-1 input bonding part IB1-1, the 1-1 line L1-1, the 1-1 output bonding part OB1-1, the 2-12 input bonding part IB2-12, the 2-8 line L2-8 and the 2-12 output bonding part OB2-12.

A state in which the voltage is applied to the substrate through the anti-static wiring ESD may be defined as a driving state. In addition, a state in which the voltage is not applied to the substrate through the anti-static wiring ESD may be defined as a non-driving state.

According to some embodiments, the connecting the first terminal of the ammeter to the 1-1 test pad TP1-1 may be performed in the non-driving state. That is, measuring the resistance of the 1-2 output bonding part OB1-2 may be performed in the non-driving state.

In the non-driving state, the 1-1 input bonding part IB1-1, the 1-1 line L1-1, and the 1-1 output bonding part OB1-1 may not apply a signal to the anti-static wiring ESD. According to some embodiments, in the non-driving state, the 1-1 input bonding part IB1-1, the 1-1 line L1-1, and the 1-1 output bonding part OB1-1 may be used to measure the resistance of the 1-2 output bonding part OB1-2. That is, in order to measure the resistance of the 1-2 output bonding part OB1-2, an additional input bonding part, a line, and an output bonding part may not be required. Accordingly, each of the number of substrate pads, the number of input pads, the number of output pads, and the number of the circuit board pads may be relatively reduced. Accordingly, each of widths of the substrate pads, widths of the input pads, widths of the output pads, and widths of the circuit board pads may increase. In addition, sufficient space may be secured in the substrate, the first chip-on film COF1, and the circuit board PCB.

According to some embodiments, connecting the first terminal of the ammeter to the 2-8 test pad TP2-8 may be performed in the non-driving state. That is, the measuring the resistance of the 2-11 output bonding part OB2-11 may be performed in the non-driving state.

In the non-driving state, the 2-12 input bonding part IB2-12, the 2-8 line L2-8, and the 2-12 output bonding part OB2-12 may not apply a signal to the anti-static wiring ESD. According to some embodiments, in the non-driving state, the 2-12 input bonding part IB2-12, the 2-8 line L2-8, and the 2-12 output bonding part OB2-12 may be used to measure the resistance of the 2-10 output bonding part OB2-10. That is, in order to measure the resistance of the 2-10 output bonding part OB2-10, an additional input bonding part, a line, and an output bonding part may not be required. Accordingly, each of the number of substrate pads, the number of input pads, the number of output pads, and the number of the circuit board pads may be relatively reduced. Accordingly, each of widths of the substrate pads, widths of the input pads, widths of the output pads, and widths of the circuit board pads may increase. In addition, sufficient space may be secured in the substrate, the second chip-on film COF2, and the circuit board PCB.

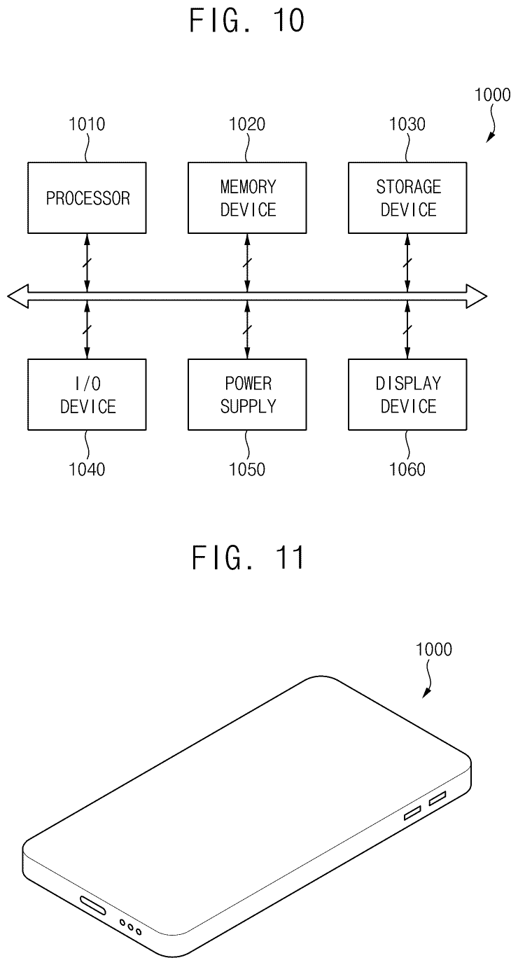

FIG. 10 is a block diagram illustrating an electronic device according to embodiments. FIG. 11 is a diagram illustrating an example in which the electronic device of FIG. 10 is implemented as a smart phone.

Referring to FIGS. 10 and 11, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 11, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

Embodiments according to the present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the appended claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a display area in which a plurality of pixels are located and a non-display area in contact with the display area;
an outer wiring in the non-display area on the substrate;
a 1-1 substrate pad in the non-display area on the substrate and connected to the outer wiring;
a first chip-on film attached to one side of the substrate and including a 1-1 output pad connected to the 1-1 substrate pad and a 1-1 input pad connected to the 1-1 output pad through a 1-1 line; and
a circuit board attached to one side of the first chip-on film and including a 1-1 circuit board pad connected to the 1-1 input pad and a 1-1 test pad connected to the 1-1 circuit board pad through a 1-1 test line.

2. The display device of claim 1, wherein the outer wiring is an anti-static wiring.

3. The display device of claim 1, further comprising:
a 1-2 substrate pad in the non-display area on the substrate and adjacent to the 1-1 substrate pad;
a 1-2 output pad in the first chip-on film, connected to the 1-2 substrate pad, and adjacent to the 1-1 output pad;
a 1-2 input pad in the first chip-on film, connected to the 1-2 output pad through a 1-2 line, and adjacent to the 1-1 input pad;
a 1-2 circuit board pad in the circuit board, connected to the 1-2 input pad, and adjacent to the 1-1 circuit board pad; and
a 1-2 test pad in the circuit board, connected to the 1-2 circuit board pad through a 1-2 test line, and adjacent to the 1-1 test pad.

4. The display device of claim 3, further comprising:
a 1-3 input pad in the first chip-on film and adjacent to the 1-2 input pad, and
wherein the 1-3 input pad is connected to the 1-2 line through a 1-3 line.

5. The display device of claim 4, further comprising:
a 1-3 substrate pad in the non-display area on the substrate and adjacent to the 1-2 substrate pad;
a 1-3 output pad in the first chip-on film, connected to the 1-3 substrate pad, and adjacent to the 1-2 output pad;
a 1-3 circuit board pad in the circuit board, connected to the 1-3 input pad, and adjacent to the 1-2 circuit board pad; and
a 1-3 test pad in the circuit board, connected to the 1-3 circuit board pad through a 1-3 test line, and adjacent to the 1-2 test pad.

6. The display device of claim 5, further comprising:
a 1-4 substrate pad in the non-display area on the substrate and adjacent to the 1-3 substrate pad;
a 1-4 output pad in the first chip-on film, connected to the 1-4 substrate pad, and adjacent to the 1-3 output pad;
a 1-4 input pad in the first chip-on film, connected to the 1-4 output pad through a 1-4 line, and adjacent to the 1-3 input pad;
a 1-4 circuit board pad in the circuit board, connected to the 1-4 input pad, and adjacent to the 1-4 circuit board pad; and
a 1-4 test pad in the circuit board, connected to the 1-4 circuit board pad through a 1-4 test line, and adjacent to the 1-3 test pad.

7. The display device of claim 6, wherein the 1-2 substrate pad and the 1-4 substrate pad are connected to each other through a 1-1 bridge line.

8. The display device of claim 7, wherein the outer wiring is connected to the 1-1 bridge line.

9. The display device of claim 8, wherein the outer wiring and the 1-1 bridge line are on different layers.

10. The display device of claim 1, wherein the 1-1 substrate pad is connected to one end of the outer wiring.

11. The display device of claim 10, further comprising:
a 2-1 substrate pad in the non-display area on the substrate and connected to other end of the outer wiring; and
a second chip-on-film attached to one side of the substrate, spaced apart from the first chip-on film, and including a 2-1 output pad connected to the 2-1 substrate pad and a 2-1 input pad connected to the 2-1 output pad through a 2-1 line.

12. The display device of claim 11, wherein the circuit board includes:
a 2-1 circuit board pad connected to the 2-1 input pad; and
a 2-1 test pad connected to the 2-1 circuit board pad through a 2-1 test line.

13. The display device of claim 12, further comprising:
a 2-2 substrate pad in the non-display area on the substrate and adjacent to the 2-1 substrate pad;
a 2-2 output pad in a second chip-on film, connected to the 2-2 substrate pad, and adjacent to the 2-1 output pad;
a 2-2 input pad in the second chip-on film, connected to the 2-2 output pad through a 2-2 line, and adjacent to the 2-1 input pad;
a 2-2 circuit board pad in the circuit board, connected to the 2-2 input pad, and adjacent to the 2-1 circuit board pad; and
a 2-2 test pad in the circuit board, connected to the 2-2 circuit board pad through a 2-2 test line, and adjacent to the 2-1 test pad.

14. The display device of claim 13, further comprising:
a 2-3 input pad in the second chip-on film and adjacent to the 2-2 input pad, and
wherein the 2-3 input pad is connected to the 2-2 line through a 2-3 line.

15. The display device of claim 14, further comprising:
a 2-3 substrate pad in the non-display area on the substrate and adjacent to the 2-2 substrate pad;
a 2-3 output pad in the second chip-on film, connected to the 2-3 substrate pad, and adjacent to the 2-2 output pad;
a 2-3 circuit board pad in the circuit board, connected to the 2-3 input pad, and adjacent to the 2-2 circuit board pad; and
a 2-3 test pad in the circuit board, connected to the 2-3 circuit board pad through a 2-3 test line, and adjacent to the 2-2 test pad.

16. The display device of claim 15, further comprising:
a 2-4 substrate pad in the non-display area on the substrate and adjacent to the 2-3 substrate pad;
a 2-4 output pad in the second chip-on film, connected to the 2-4 substrate pad, and adjacent to the 2-3 output pad;
a 2-4 input pad in the second chip-on film, connected to the 2-4 output pad through a 2-4th line, and adjacent to the 2-3 input pad;
a 2-4 circuit board pad in the circuit board, connected to the 2-4 input pad, and adjacent to the 2-3 circuit board pad; and
a 2-4 test pad in the circuit board, connected to the 2-4 circuit board pad through a 2-4 test line, and adjacent to the 2-3 test pad.

17. A method of measuring resistance of a display device, the method comprising:
connecting a first output pad in a chip-on film to a first substrate pad in a non-display area of a substrate, wherein the first substrate pad is connected to an outer wiring;
connecting a first input pad in the chip-on film to a first circuit board pad included in a circuit board, wherein the first input pad is connected to the first output pad through a first line; and
connecting a first terminal of an ammeter to a first test pad included in the circuit board, wherein the first test pad is connected to the first circuit board pad through a first test line.

18. The method of claim 17, further comprising:
connecting a second output pad in the chip-on film to a second substrate pad in the non-display area of the substrate, wherein the second substrate pad is adjacent to the first substrate pad;
connecting a second input pad connected to the second output pad through a second line to a second circuit board pad in the circuit board, wherein the second circuit board pad is adjacent to the first circuit board pad;
connecting a second terminal of the ammeter to a second test pad in the circuit board and connected to the second circuit board pad through a second test line, wherein the second test line is adjacent to the first test line;
connecting a first terminal of a voltmeter to a third test pad in the circuit board, wherein the third test pad is adjacent to the second test pad; and
connecting a second terminal of the voltmeter to a fourth test pad in the circuit board, wherein the fourth test pad is adjacent to the third test pad.

19. The method of claim 18, further comprising:
forming a bridge line connecting the outer wiring and the second substrate pad.

20. The method of claim 17, wherein the connecting the first terminal of the ammeter to the first test pad is performed when a voltage is not applied to the substrate through the outer wiring.

21. An electronic device comprising:
a substrate including a display area in which a plurality of pixels are located and a non-display area in contact with the display area;
an outer wiring in the non-display area on the substrate;
a 1-1 substrate pad in the non-display area on the substrate and connected to the outer wiring;
a first chip-on film attached to one side of the substrate and including a 1-1 output pad connected to the 1-1 substrate pad and a 1-1 input pad connected to the 1-1 output pad through a 1-1 line;
a circuit board attached to one side of the first chip-on film and including a 1-1 circuit board pad connected to the 1-1 input pad and a 1-1 test pad connected to the 1-1 circuit board pad through a 1-1 test line; and
a memory device configured to store data.
